(19) United States
(12) Patent Application Publication
(10) Pub. No.: US 2026/0362987 A1
(43) Pub. Date: Nov. 12, 2026

(54) SYSTEMS AND METHODS FOR FABRICATION OF SUPERCONDUCTING INTEGRATED CIRCUITS HAVING FLIP-CHIP ARRANGEMENTS WITH HIGH COHERENCE DEVICES

(71) Applicant: 1372934 B.C. LTD., Burnaby (CA)

(72) Inventors: Timothy L. Duty, Vancouver (CA); Mohammad H. Amin, Coquitlam (CA); Andrew J. Berkley, Vancouver (CA); Berta Trullas Clavera, Vancouver (CA)

(21) Appl. No.: 19/102,067

(22) PCT Filed: Aug. 8, 2023
(86) PCT No.: PCT/US2023/071836

§ 371 Date: Feb. 7, 2025

Related U.S. Application Data
(60) Provisional application No. 63/396,340, filed on Aug. 9, 2022.

(51) Int. Cl. H10N 69/00; G06N 10/40

(52) U.S. Cl. CPC H10N 69/00; G06N 10/40

(57) ABSTRACT

A superconducting circuit can be fabricated to provide a scalable quantum processor with flexible control and a plurality of highly coherent qubits. The superconducting circuit includes: a superconducting device layer on a surface of a first chip and a shield layer on a surface of a second chip. The two chips are communicatively coupled in a flip-chip configuration, such that there is a space or gap consisting of: air, a vacuum, and/or a partial vacuum, and the superconducting device layer and the second chip are non-galvanically coupled. In a shield flip-chip implementation, the first chip includes a multi-layer stack and the second chip provides shield. In a control flip-chip implementation, the second chip includes a multi-layer control stack having a communicative interface on an external layer to transmit control signals across the space or the gap to high-coherence qubits devices on the first chip.

### CROSS-REFERENCE TO RELATED APPLICATION

This patent application claims priority of U.S. Patent Application No. 63/396,340, filed on Aug. 9, 2022, the entire disclosure of which is hereby incorporated by reference herein for all purposes.

### TECHNICAL FIELD

This disclosure generally relates to systems and methods for fabrication of superconducting integrated circuits for quantum processors with improved coherence, and, more specifically, to systems and methods for fabrication of superconducting integrated circuits and/or for fabrication of superconducting scalable quantum processors with improved device coherence through the use of multi-chip arrangements.

### BACKGROUND

### Superconducting Integrated Circuits

Superconductivity is a set of physical properties observed in a material where electrical resistance of the material vanishes and magnetic flux fields are expelled from the material. A material exhibiting these properties is referred to in the present application as a superconductor. A superconductor typically has a characteristic critical temperature below which its electrical resistance drops to zero. A material exhibiting these properties is also referred to in the present application as a superconducting material. A superconducting material may be a superconducting metal, for example. Niobium is a superconducting metal that becomes superconducting below 9.2 K. An electric current in a loop of superconducting material can persist indefinitely with no power source.

An integrated circuit (also referred to in the present application as a chip) is one or more electronic circuits on a single piece (or “chip”) substrate. In some implementations, the substrate is silicon. In other implementations, the substrate is sapphire. Integration of large numbers of devices on a chip can result in circuits that are orders of magnitude smaller, faster, and less expensive than circuits constructed of discrete electronic components.

A superconducting integrated circuit is an integrated circuit that includes superconducting material. A superconducting circuit (e.g., a superconducting integrated circuit) may include one or more superconducting devices. Where the superconducting integrated circuit includes a superconducting quantum processor, a superconducting device of the superconducting integrated circuit may be a superconducting qubit, a coupling device, a readout device, or a flux storage device, for example.

### Superconducting Processor

A quantum processor may take the form of a superconducting processor. However, superconducting processors can include processors that are not intended for quantum computing. For instance, some embodiments of a superconducting processor may not focus on quantum effects such as quantum tunneling, superposition, and entanglement but may rather operate by emphasizing different principles, such as for example the principles that govern the operation of classical computer processors. However, there may still be certain advantages to the implementation of such superconducting “classical” processors. Due to their natural physical properties, superconducting classical processors may be capable of higher switching speeds and shorter computation times than non-superconducting processors, and therefore it may be more practical to solve certain problems on superconducting classical processors. The present articles and methods are particularly well-suited for use in fabricating both superconducting quantum processors and superconducting classical processors.

### Superconducting Qubits

Superconducting qubits are a type of superconducting quantum device that can be included in a superconducting integrated circuit. Superconducting qubits can be separated into several categories depending on the physical property used to encode information. For example, superconducting qubits may be separated into charge, flux and phase devices. Charge devices store and manipulate information in the charge states of the device. Flux devices store and manipulate information in a variable related to the magnetic flux through some part of the device. Phase devices store and manipulate information in a variable related to the difference in superconducting phase between two regions of the device. Superconducting qubits commonly include at least one Josephson junction. A Josephson junction is a small interruption in an otherwise continuous superconducting current path and is typically realized by a thin insulating barrier sandwiched between two superconducting electrodes. Thus, a Josephson junction may be implemented as a three-layer or “tri-layer” structure. Superconducting qubits are further described in, for example, U.S. Pat. Nos. 7,876,248, 8,035,540, and 8,098,179.

### Quantum Processor

A quantum processor may take the form of a superconducting quantum processor. A superconducting quantum processor may include a number of superconducting qubits and associated local bias devices. A superconducting quantum processor may also include couplers (also known as coupling devices or qubit couplers) that selectively provide communicative coupling between qubits.

Superconducting qubits are solid state qubits based on circuits of superconducting materials. Operation of superconducting qubits is based on the underlying principles of magnetic flux quantization, and Josephson tunneling. Superconducting effects can be present in different configurations and can give rise to different types of superconducting qubits including flux, phase, charge, and hybrid qubits. The different configurations can vary in the topology of the loops, the placement of the Josephson junctions, and the physical parameters of elements of the superconducting circuits, such as inductance, capacitance, and Josephson junction critical current.

In one implementation, the superconducting qubit includes a superconducting loop interrupted by a Josephson junction. The inductance and the critical current may be selected, adjusted, or tuned, to increase the ratio of the inductance of the Josephson junction to the geometric inductance of the superconducting loop, and to cause the qubit to be operable as a bistable device. In some implementations, the ratio of the inductance of the Josephson junction to the geometric inductance of the superconducting loop of a qubit is approximately equal to three.

In one implementation, the superconducting coupler includes a superconducting loop interrupted by a Josephson junction. The inductance and the critical current may be selected, adjusted, or tuned, to decrease the ratio of the inductance of the Josephson junction to the geometric inductance of the superconducting loop, and to cause the coupler to be operable as a monostable device. In some implementations, the ratio of the inductance of the Josephson junction to the geometric inductance of the superconducting loop of a coupler is approximately equal to, or less than, one.

Further details and embodiments of quantum processors that may be used in conjunction with the present systems and devices are described in, for example, U.S. Pat. Nos. 7,533,068; 8,008,942; 8,195,596; 8,190,548; and 8,421,053.

### Noise in a Quantum Processor

A quantum processor may require a local bias to be applied on a qubit to implement a problem Hamiltonian. The local bias applied on the qubit depends on persistent current Iₚ and external flux bias φ_{q} as described below:

δhᵢ=2|I_{P}|δφ_{q}

Noise affects the local bias δhᵢ in the same way as the external flux bias φ_{q} and thus changes the specification of the qubit terms in the problem Hamiltonian. By altering the problem Hamiltonian, noise may introduce errors into the computational result from quantum annealing.

Low-noise is a desirable characteristic of quantum devices. Noise can compromise or degrade the functionality of the individual devices, such as superconducting qubits, and of the superconducting processor as a whole. For instance, in quantum processors performing quantum annealing, noise can negatively affect qubit coherence and reduce the efficacy of qubit tunneling. Since noise is a serious concern to the operation of quantum processors, measures should be taken to reduce noise wherever possible so that a transition from coherent to incoherent tunneling is not induced by the environment.

Impurities may be deposited on the metal surface and/or may arise from an interaction with the etch/photoresist chemistry and the metal. Noise can be caused by impurities on the upper surface of the quantum processor. In some cases, superconducting devices that are susceptible to noise are fabricated in the top wiring layers of a superconducting integrated circuit and are thus sensitive to post-fabrication handling. There is a risk of introducing impurities that cause noise during post-fabrication handling. One approach to reducing noise is using a barrier passivation layer, for example, an insulating layer, to overlie the topmost wiring layer. The use of a barrier passivation layer to minimize noise from impurities on the upper surface of a quantum processor is described in U.S. Patent Application No. 2018/02219150.

Noise can also result from an external environment or surrounding circuitry in a superconducting processor. In a quantum processor, flux noise on qubits interferes with properly annealing the quantum processor because of the steep transition between qubit states as the flux bias is swept. Flux noise can be a result of current flowing through wiring of other devices included in the superconducting processor and can have a particularly negative effect on qubits at their respective degeneracy points. For example, flux noise can introduce errors in calculations carried out by the superconducting processor due to inaccuracies in setting flux bias and coupling strength values. Reducing or even eliminating such inaccuracies may be particularly advantageous in using an integrated circuit as part of a quantum processor. Much of the static control error can be designed out of the processor with careful layout and high-precision flux sources, as well as by adding circuitry, such as an on-chip shield, to tune away any non-ideal flux qubit behavior. However, in many cases, limitations in integrated circuit fabrication capabilities can make it difficult to address noise by changing processor layout and adding circuitry. There is therefore a general desire for articles and methods to for fabricating integrated circuits that have reduced flux noise (and thus improved coherence) without having to compromise the quantum processor layout by adding additional layers or circuitry.

### Shielding and Noise

Magnetic fields produced by external sources may cause unwanted interactions with devices in the integrated circuit. Accordingly, there may be a need for a superconductive shield proximate to devices populating the integrated circuit to reduce the strength of interference such as magnetic and electrical fields.

Superconductive shield layers may be used in single flux quantum (SFQ) or rapid single flux quantum (RSFQ) technology to separate devices from DC power lines that could otherwise undesirably bias the devices. The devices populate the integrated circuit but are separated from the DC power lines by placing a ground plane between the devices and the DC power line.

In SFQ circuits, ground planes and shield layers are terminologies used interchangeably. A ground plane in SFQ integrated circuit is a layer of metal that appears to most signals within the circuit as an infinite ground potential. The ground plane helps to reduce noise within the integrated circuit but may be used to ensure that all components within the SFQ integrated circuits have a common potential to compare voltage signals. Contacts can be used between wiring layers and a ground plane throughout SFQ circuitry.

Supercurrent flowing in superconducting wires has an associated magnetic field in the same manner as electrons flowing in normal metal wires. Magnetic fields can couple inductively to superconducting wires, inducing currents to flow. Quantum information processing with superconducting integrated circuits necessarily involves supercurrents moving in wires, and hence associated magnetic fields.

The quantum properties of quantum devices are very sensitive to noise, and stray magnetic fields in superconducting quantum devices can negatively impact the quantum information processing properties of such circuits. Superconducting ground planes have been used in the art to reduce cross-talk between control lines and devices. However, such approaches have only been used in superconducting integrated circuits for classical processing and sensor applications, which are relatively robust against in-circuit noise and operate at significantly higher temperatures as compared with superconducting quantum processing integrated circuits.

In superconducting quantum processing integrated circuits, it is desirable to substantially attenuate and control unwanted cross-talk between devices, otherwise quantum information processing at commercial scales may not be possible. The present methods, systems and apparatus provide techniques for attenuating cross-talk in superconducting quantum processing integrated circuits between quantum devices in order to support the desired quantum effects and controllably couple quantum devices in a manner that permits exchange of coherent quantum information.

### Flip-Chip

Flip-chip is a method for interconnecting devices (e.g., integrated circuits) to external circuitry using solder bumps deposited on contact pads. The solder bumps are also referred to in the present application as bump bonds. Bump bonds may include indium, for example, in which case they are also referred to in the present application as indium bump bonds.

In some implementations, bump bonds are deposited on contact pads on a top side of a chip during fabrication. In order to mount the chip to an external circuit (e.g., a circuit board or another chip), the chip is flipped over relative to the external circuit so that an upper surface of the chip faces down, and arranged so that its contact pads align with matching contact pads on an upper surface of the external circuit, and then the solder is reflowed to complete the interconnect. This is in contrast to wire bonding, in which the chip is mounted upright, and wires are used to interconnect contact pads to external circuitry.

### Kinetic Inductance

Current flowing through a metal material in principle stores energy both in the magnetic field of that metal and in the kinetic energy of the charge carriers (e.g., the electrons or Cooper pairs). In non-superconducting metals, the charge carriers collide frequently with the lattice and lose their kinetic energy as Joule heating. This is also referred to as scattering, and quickly releases energy. However, in superconducting materials, scattering is substantially reduced, as the charge carriers are Cooper pairs which are protected against dissipation through scattering. This allows for superconducting materials to store energy in the form of kinetic inductance. This phenomenon allows kinetic inductance to efficiently store energy within the superconducting metal. Kinetic inductance is at least in part determined by the inertial mass of the charge carriers of a given material and increases as carrier density decreases. As the carrier density decreases, a smaller number of carriers must have a proportionally greater velocity in order to produce the same current. Materials that have high kinetic inductance for a given area (as defined below) are referred to as “kinetic inductance materials”, or “high kinetic inductance materials”.

Kinetic inductance materials are those that have a high normal-state resistivity and/or a small superconducting energy gap, resulting in a larger kinetic inductance per unit of area. In general, total inductance L of a superconducting material is given by L=L_{K}+L_{G}, where L_{G} is the geometric inductance and L_{K} is the kinetic inductance. The kinetic inductance of a superconducting film in near-zero temperatures is proportional to the effective penetration depth λ_{eff}. In particular, for a film with a given thickness t, the kinetic inductance of the film is proportional to the ratio of the length of the film L to the width of the film W, where length is in the direction of the current and width is orthogonal to length (note that both width and length are orthogonal to the dimension in which thickness is measured). That is,

$${L}_{K} ∼ {λ}_{eff} \frac{L}{W}$$

for a superconducting film with a given thickness. The kinetic inductance fraction of a material is characterized as

$$α = \frac{{L}_{k}}{{L}_{g} + {L}_{k}} .$$

A material considered to have high kinetic inductance would typically have α in the range of 0.1<α≤1. Materials with less than 10% of the energy stored as kinetic inductance would be considered traditional magnetic storage inductors with a small correction.

In some implementations it may be beneficial to attempt to maximize kinetic inductance in minimal volume. This may include attempting to minimize the width of the film, selecting a suitable material with a high effective penetration depth λ_{eff}, and selecting a length for the film which achieves the desired kinetic inductance. It may also be beneficial to attempt to minimize the thickness t of the material, subject to fabrication constraints, as for t<3λ_{eff(bulk)} (where λ_{eff(bulk)} is the effective penetration depth of the material in bulk, not thin-film), λ_{eff} increases at least approximately proportionately to 1/t². In some implementations, t<n·λ_{eff(bulk)}, where n is some value substantially less than 1 (e.g., 0.5, 0.1, 0.05, 0.01, etc.).

### Integrated Circuit Fabrication

Traditionally, the fabrication of superconducting integrated circuits has not been performed at state-of-the-art semiconductor fabrication facilities. This may be due to the fact that some of the materials used in superconducting integrated circuits can contaminate the semiconductor facilities. For instance, gold may be used as a resistor in superconducting circuits, but gold can contaminate a fabrication tool used to produce CMOS wafers in a semiconductor facility. Consequently, superconducting integrated circuits containing gold are typically not processed by tools which also process CMOS wafers.

Superconductor fabrication has typically been performed in research environments where standard industry practices could be optimized for superconducting circuit production. Superconducting integrated circuits are often fabricated with tools that are similar to those traditionally used to fabricate semiconductor chips or integrated circuits. Due to issues unique to superconducting circuits, not all semiconductor processes and techniques are necessarily transferrable to superconductor chip manufacture. Transforming semiconductor processes and techniques for use in superconductor chip and circuit fabrication often requires changes and fine adjustments. Such changes and adjustments typically are not obvious and may require a great deal of experimentation. The semiconductor industry faces problems and issues not necessarily related to the superconducting industry. Likewise, problems and issues that concern the superconducting industry are often of little or no concern in standard semiconductor fabrication.

Any impurities within superconducting chips may result in noise which can compromise or degrade the functionality of the individual devices, such as superconducting qubits, and of the superconducting chip as a whole. Since noise is a serious concern to the operation of quantum computers, measures should be taken to reduce dielectric noise wherever possible.

The art of integrated circuit fabrication typically involves multiple processes that may be sequenced and/or combined to produce a desired effect. Example systems and methods for superconducting integrated circuit fabrication that may be combined, in whole or in part, with at least some embodiments of the present systems and methods are described in U.S. Pat. Nos. 8,951,808 and 9,768,371, which are incorporated herein by reference in their entirety.

### Etching

Etching removes layers of, for example, substrates, dielectric layers, oxide layers, electrically insulating layers and/or metal layers according to desired patterns delineated by photoresists or other masking techniques. Two example etching techniques are wet chemical etching and dry chemical etching.

Wet chemical etching or “wet etching” is typically accomplished by submerging a wafer in a corrosive bath such as an acid bath. In general, etching solutions are housed in polypropylene, temperature-controlled baths. The baths are usually equipped with either a ring-type plenum exhaust ventilation or a slotted exhaust at the rear of the etch station. Vertical laminar-flow hoods are typically used to supply uniformly-filtered, particulate-free air to the top surface of the etch baths.

Dry chemical etching or “dry etching” is commonly employed due to its ability to better control the etching process and reduce contamination levels. Dry etching effectively etches desired layers through the use of gases, either by chemical reaction such as using a chemically reactive gas or through physical bombardment, such as plasma etching, using, for example, argon atoms.

Plasma etching systems have been developed that can effectively etch, for 5 example, silicon, silicon dioxide, silicon nitride, aluminum, tantalum, tantalum compounds, chromium, tungsten, gold, and many other materials. Two types of plasma etching reactor systems are in common use—the barrel reactor system and the parallel plate reactor system. Both reactor types operate on the same principles and vary primarily in configuration only. The typical reactor consists of a vacuum reactor chamber made usually of aluminum, glass, or quartz. A radiofrequency or microwave energy source (referred to collectively as RF energy source) is used to activate fluorine-based or chlorine-based gases which act as etchants. Wafers are loaded into the chamber, a pump evacuates the chamber, and the reactant gas is introduced. The RF energy ionizes the gas and forms the etching plasma, which reacts with the wafers to form volatile products which are pumped away.

Physical etching processes employ physical bombardment. For instance, argon gas atoms may be used to physically bombard a layer to be etched, and a vacuum pump system is used to remove dislocated material. Sputter etching is one physical technique involving ion impact and energy transfer. The wafer to be etched is attached to a negative electrode, or “target,” in a glow-discharge circuit. Positive argon ions bombard the wafer surface, resulting in the dislocation of the surface atoms. Power is provided by an RF energy source. Ion beam etching and milling are physical etching processes which use a beam of low-energy ions to dislodge material. The ion beam is extracted from an ionized gas (e.g., argon or argon/oxygen) or plasma, created by an electrical discharge.

Reactive ion etching (RIE) is a combination of chemical and physical etching. During RIE, a wafer is placed in a chamber with an atmosphere of chemically reactive gas (e.g., CF₄, CCl₄, CHF₃, and many other gases) at a low pressure. An electrical discharge creates an ion plasma with an energy of a few hundred electron volts. The ions strike the wafer surface vertically, where they react to form volatile species that are removed by the low pressure in-line vacuum system.

### Planarization

The use of chemical-mechanical planarization (CMP) allows for a nearly flat surface to be produced. CMP is a standard process in the semiconductor industry. The CMP process uses an abrasive and corrosive chemical slurry in conjunction with a polishing pad and retaining ring that are pressed together by a dynamic polishing head. This removes material and tends to even out any irregular topography, making the wafer flat or planar.

The foregoing examples of the related art and limitations related thereto are intended to be illustrative and not exclusive. Other limitations of the related art will become apparent to those of skill in the art upon a reading of the specification and a study of the drawings.

### BRIEF SUMMARY

It is advantageous for superconducting qubits used in quantum computing to be highly coherent in order for computation to be performed before quantum information is lost, and for a quantum processor to be operable to solve complex problems that require a large number of variables. Reduction in a number of interfaces and/or galvanic connections to controllable superconducting devices can reduce device coherence, but inclusion of additional devices and/or structures as part of the fabrication stack can increase a number of qubits available for problem solving and flexibility of the quantum processor. The use of low-loss materials, dielectrics such as air and/or a vacuum, and shield structures can be used to control undesired fields and mitigate noise that may negatively affect computation results without limiting processor functionality.

Described herein is a superconducting circuit and a method of fabrication thereof that includes two chips in a flip-chip configuration with a space or a gap therebetween. A main chip includes at least highly coherent controllable superconducting devices, and a flip chip includes at least a superconductive shield layer that reduces magnetic and electrical interference between devices. A multi-layer control stack for control, addressing, and/or readout of the superconducting devices may be located on either the main chip or the flip chip for increased flexibility and functionality of the superconducting circuit.

In an aspect, there is provided a superconducting circuit. The superconducting circuit may comprise a first chip, where a superconducting device layer is a portion of a first surface of the first chip, and the superconducting device layer includes at least a portion of at least one superconducting device. The superconducting circuit may comprise a second chip, where a superconductive shield layer is at least a portion of a first surface of the second chip, and the second chip is communicatively coupled to the first chip such that the first surfaces of the first chip and the second chip face one another. The superconducting device layer and the first surface of the second chip may be non-galvanically coupled, and physically separated by a space or a gap, and the space or the gap consisting of at least one of: air, a vacuum, and a partial vacuum. A combination of the superconductive shield layer and the space or the gap reduces magnetic and electrical interference between superconducting devices in the superconducting device layer.

In some implementations, at least one of the first chip and the second chip may be mechanically coupled to one another or to an additional surface such that a fixed distance is maintained between the superconducting device layer and the first surface of the second chip.

In some implementations, the additional surface may comprise an electrically insulating material.

In some implementations, the at least one of the first chip and the second chip may be mechanically coupled to one another or to the additional surface by a mechanical coupler, and the mechanical coupler may: couple at least one of the first chip and the second chip to a fixed external surface, or couple the first chip to the second chip, where the mechanical coupler is coupled to the first chip at a location that avoids physical contact and conductive coupling with the superconducting device layer.

In some implementations, the space or the gap may be provided by a trench on the first surface of the second chip, the trench may be located along a cross-section of the superconducting circuit that is centered around the superconducting device layer, the trench may have a trench width exceeding a width of the superconducting device layer, and the first chip may lie flush against a region of the first surface of the second chip that does not include the trench, such that side walls of the trench at least partially surround the superconducting device layer.

In some implementations, communicative coupling of the second chip to the first chip may include an adhesive to mechanically couple the region of the first surface of the second chip that does not include the trench to the first chip.

In some implementations, the superconductive shield layer may comprise a superconducting metal that exhibits superconducting behavior at and below a critical temperature. The superconducting metal may be one of: aluminum, niobium, and tantalum.

In some implementations, the first chip may comprise a ground plane, and the ground plane may occupy a second portion of the first surface of the first chip.

In some implementations, the at least a portion of at least one superconducting device may comprise at least a portion of one or more superconducting qubits.

In some implementations, the at least a portion of the one or more superconducting qubits may include a respective superconducting loop of each of the one or more superconducting qubits.

In some implementations, the least a portion of the one or more superconducting qubits may include a respective Josephson junction of each of the one or more superconducting qubits.

In some implementations, the at least a portion of at least one superconducting device may comprise: at least a portion of at least two superconducting qubits and at least a portion of at least one coupling device, and the at least one coupling device may be operable to provide communicative coupling between the at least two superconducting qubits.

In some implementations, the at least a portion of at least two superconducting qubits and the at least a portion of at least one coupling device may comprise, for each superconducting qubit and each coupling device, one or more of: a superconducting loop and a Josephson junction.

In some implementations, the at least a portion of the at least one superconducting device in the superconducting device layer comprises a low-noise superconducting material. The low-noise superconducting material exhibits superconducting behavior at and below a critical temperature.

In some implementations, the low-noise superconducting material comprises aluminum.

In some implementations, the second chip may comprise a second chip substrate that lies adjacent to the superconductive shield layer, and the second chip substrate may have an external surface that opposes the superconductive shield layer. The first chip may comprise a first chip substrate and a multi-layer stack, in which the first chip substrate may have an external surface that opposes the superconducting device layer, the multi-layer stack may lie between the superconducting device layer and the first chip substrate, and the multi-layer stack may include an external stack layer that lies adjacent to the superconducting device layer.

In some implementations, the external stack layer of the multi-layer stack comprises a low-loss insulating material.

In some implementations, the low-loss insulating material may be one of: a single-crystal silicon or sapphire.

In some implementations, the at least a portion of at least one superconducting device may include, for each superconducting device, a respective superconducting loop.

In some implementations, a second portion of each superconducting device is a respective Josephson junction, and each Josephson junction lies within the superconducting device layer.

In some implementations, a second portion of each superconducting device may comprise a respective Josephson junction that lies within the multi-layer stack in one of: a layer in near proximity to the noise-susceptible device layer or a layer in near proximity to the first chip substrate. The second portion of each superconducting device may further comprise a via plated with a superconducting material that superconductingly electrically couples the Josephson junction to a respective superconducting loop.

In some implementations, the second chip may comprise a multi-layer control stack adjacent to the superconductive shield layer, the multi-layer control stack can include at least one superconducting device control circuit that comprises at least one communicative interface. The at least one communicative interface is located on an external stack layer of the multi-layer layer control stack and lies adjacent to the space or the gap. The first chip may include a first chip substrate that lies adjacent to the superconducting device layer.

In some implementations, the at least one communicative interface may be operable to inductively communicate with the at least one superconducting device on the first chip.

In some implementations, the external layer of the multi-layer control stack may occupy a second portion of the first surface of the second chip, such that each communicative interface of the at least one communicative interface is aligned along a cross-section of the superconducting circuit with a respective superconducting device of the at least one superconducting device in the superconducting device layer.

In some implementations, a depth of the space or the gap that separates the at least one communicative interface from the at least one superconducting device in the superconducting device layer has a size such that control signals are transmissible thereacross.

In some implementations, the space or the gap may be provided by a trench on the first surface of the second chip, the trench may be located along a cross-section of the superconducting circuit that is centered around the superconducting device layer and includes a location of the at least one communicative interface, the trench may have a trench width exceeding a width of the superconducting device layer, and the first chip may lie flush against a portion of the first surface of the second chip occupied by the superconductive shield layer, such that a number of side walls of the trench partially surround the superconducting device layer and the at least one communicative interface.

In some implementations, the first chip may include a first chip substrate that comprises an electrically insulating material, in which an external surface of the first chip substrate is a second surface of the first chip that opposes the superconducting device layer. The second chip may include a second chip substrate that comprises a same or different electrically insulating material, in which an external surface of the second chip substrate is a second surface of the second chip that opposes the superconductive shield layer.

In some implementations, the first chip substrate may comprise one of: sapphire, quartz, and single-crystal silicon, and the second chip substrate may comprise a same or different one of: sapphire, quartz, and single-crystal silicon.

In some implementations, at least the first chip substrate may comprise a substrate material having a loss tangent less than 10⁶.

In some implementations, the superconductive shield layer of the second chip may be electrically coupled to the ground plane of the first chip at one or more locations.

In some implementations, at least one bump bond may electrically couple the superconductive shield layer of the second chip to the ground plane of the first chip.

In an implementation, there is provided a method of fabrication of a superconducting circuit. The method may include forming a superconducting device layer on a portion of a first surface of a first chip, where the superconducting device layer includes at least a portion of at least one superconducting device; forming a superconductive shield layer on at least a portion of a first surface of a second chip; and communicatively coupling the first chip to the second chip such that the first surfaces of the first chip and the second chip face one another. The communicatively coupling may include non-galvanically communicatively coupling the superconducting device layer and the first surface of the second chip. The non-galvanically coupling may include: physically separating the superconducting device layer and the first surface of the second chip by a space or a gap, where the space or the gap consisting of at least one of: air, a vacuum, and a partial vacuum, and a combination of the superconductive shield layer and the space or the gap may reduce magnetic and electrical interference between superconducting devices in the superconducting device layer.

In some implementations, the communicatively coupling the first chip to the second chip may further comprise mechanically coupling at least one of the first chip and the second chip to one another or to an additional surface, and the mechanically coupling the at least one of the first chip and the second chip may be to maintain a fixed distance between the superconducting device layer and the first surface of the second chip.

In some implementations, the mechanically coupling the at least one of the first chip and the second chip to one another or to the additional surface may comprise mechanically coupling the at least one of the first chip and the second chip to the additional surface, where the additional surface comprises an electrically insulating material.

In some implementations, the mechanically coupling the at least one of the first chip and the second chip to one another or to the additional surface may comprise use of a mechanical coupler for one of: coupling at least one of the first chip and the second chip to a fixed external surface, and coupling the first chip to the second chip, where the mechanical coupler is coupled to the first chip at a location that avoids physical contact and conductive coupling with the superconducting device layer.

In some implementations, physically separating the superconducting device layer and the first surface of the second chip may comprise: determining a region along a cross-section of the superconductive shield layer that is aligned with the superconducting device layer when the first surfaces of the first chip and the second chip are arranged to face one another; etching a portion of material from the superconductive shield layer having a trench width exceeding a width of the determined region and being centered around the determined region to form a trench; and arranging the first chip to lie flush against an unetched portion of the superconductive shield layer in a flip-chip configuration to close the trench, in which side walls of the trench at least partially surround the superconducting device layer.

In some implementations, the communicatively coupling the first chip to the second chip may further comprise mechanically coupling the unetched portion of the superconductive shield layer to the first chip using an electrically non-conductive adhesive.

In some implementations, the forming the superconductive shield layer may comprise depositing a superconducting metal layer on the second chip including one of: aluminum, niobium, and tantalum.

In some implementations, the method may further comprise forming a ground plane on a second portion of the first surface of the first chip.

In some implementations, the forming the superconducting device layer may comprise forming at least a portion of one or more superconducting qubits.

In some implementations, the forming at least a portion of one or more superconducting qubits may comprise forming a respective superconducting loop of each one of the one or more superconducting qubits.

In some implementations, the forming at least a portion of one or more superconducting qubits may comprise forming a respective Josephson junction of each one of the one or more superconducting qubits using double-angle evaporation or a single-layer fabrication technique.

In some implementations, the forming the superconducting device layer may comprise forming at least a portion of at least two superconducting qubits and forming at least a portion of at least one coupling device, in which the at least one coupling device is operable to provide communicative coupling between the at least two superconducting qubits.

In some implementations, the forming at least the portion of at least two superconducting qubits and the at least a portion of at least one coupling device may comprise, for each superconducting qubit and each coupling device, one or more of: forming a superconducting loop, and forming a Josephson junction.

In some implementations, the forming the superconducting device layer may comprise forming the at least a portion of the at least one superconducting device from a low-noise superconducting material that exhibits superconducting behavior at and below a critical temperature.

In some implementations, the forming the at least a portion of the at least one superconducting device from a low-noise superconducting material may comprise forming the at least a portion of the at least one superconducting device from aluminum.

In some implementations, the first chip may include a first chip substrate that includes an external surface of the first chip that opposes the superconducting device layer, and the second chip includes a second chip substrate having an external surface of the second chip that opposes the superconductive shield layer. The forming the superconductive shield layer may comprise forming the superconductive shield layer adjacent to the second chip substrate. The forming the superconducting device layer on a portion of the first surface of the first chip may comprise forming the superconducting device layer on an external stack layer of a multi-layer stack, in which the multi-layer stack is formed between the superconducting device layer and the first chip substrate.

In some implementations, the method may further comprise forming the external stack layer of the multi-layer stack from a low-loss insulating material.

In some implementations, the forming the external layer of the multi-layer stack from the low-loss insulating material may comprise forming the low-loss insulator from a single-crystal silicon or sapphire.

In some implementations, the forming the superconducting device layer on a portion of the first surface of the first chip may comprise forming a first portion of the at least one superconducting device in the superconducting device layer, and for each superconducting device, the forming the first portion of the at least one superconducting device may comprise forming a respective superconducting loop.

In some implementations, for each superconducting device, forming a second portion of the at least one superconducting device may comprise forming a respective Josephson junction in the superconducting device layer.

In some implementations, for each superconducting device, forming a second portion of the at least one superconducting device may comprise: forming a respective Josephson junction within the multi-layer stack in one of: a layer in near proximity to the noise-susceptible device layer or a layer in near proximity to the first chip substrate, and forming a via to connect the Josephson junction to a respective first portion of the superconducting device, and plating the via with a superconducting material to superconductingly electrically couple the respective first and the second portions of the superconducting device.

In some implementations, the method may further comprise forming a multi-layer control stack adjacent to the superconductive shield layer, the multi-layer control stack may include at least one superconducting device control circuit that comprises at least one communicative interface. The forming the multi-layer control circuit comprises forming an external stack layer including the at least one communicative interface, which lies adjacently to the space or the gap. The forming of the superconducting device layer on the first surface of the first chip may comprise forming the superconducting device layer to lie adjacent to a first chip substrate.

In some implementations, the forming the external stack layer including the at least one communicative interface may comprise forming the at least one communicative interface to be operable to inductively communicate with the at least one superconducting device on the first chip.

In some implementations, the forming the external stack layer including the at least one communicative interface adjacent to the superconductive shield layer may comprise: forming the external stack layer of the multi-layer control stack on a second portion of the first surface of the second chip, in which determining a location of the second portion of the first surface of the second chip may include aligning the at least one communicative interface with a respective superconducting device of the at least one superconducting device in the superconducting device layer.

In some implementations, the physically separating the superconducting device layer and the first surface of the second chip by the space or the gap may comprise separating the at least one communicative interface at a depth from the at least one superconducting device in the superconducting device layer, and the depth may have a size such that control signals are transmissible between the at least one communicative interface and the at least one superconducting device across the space or the gap.

In some implementations, the forming the superconductive shield layer may comprise: forming the superconductive shield layer adjacent to the external stack layer of the multi-layer control stack; and etching a portion of material from at least the superconductive shield layer that overlies the at least one communicative interface to form a trench, such that the at least one communicative interface is on a surface of the trench adjacent to the space or the gap, and the trench having a trench width exceeding a width of the superconducting device layer and being centered around the superconducting device layer when the first and the second chip are aligned. The physically separating the superconducting device layer and the first surface of the second chip to form the space or the gap may comprise: closing the trench when the first surfaces of the first chip and second the second chip face one another by arranging the first chip to lie flush against an unetched portion of the superconductive shield layer, such that side walls of the trench at least partially surround the at least one communicative interface and the superconducting device layer.

In some implementations, the method may further comprise: forming the first chip having a first substrate comprised of an electrically insulating material, in which an external surface of the first substrate is a second surface of the first chip that opposes the superconducting device layer; and, forming the second chip having a second substrate comprising a same or different electrically insulating material, in which an external surface of the second substrate is a second surface of the second chip that opposes the superconductive shield layer.

In some implementations, the forming the first chip having the first substrate and the forming the second chip having the second substrate may comprise forming the first substrate from one of: sapphire, quartz, and a single-crystal silicon, and forming the second substrate from a same or different one of: sapphire, quartz, and a single-crystal silicon.

In some implementations, at least the forming the first chip having the first substrate may comprise forming the first chip from a substrate material having a loss tangent less than 10⁶.

In some implementations, the method may further comprise electrically coupling the superconductive shield layer of the second chip to the ground plane of the first chip at one or more locations.

In some implementations, the electrically coupling the superconductive shield layer of the second chip to the ground plane of the first chip may include forming at least one bump bond between the superconductive shield layer of the second chip and the ground plane of the first chip.

In an implementation, there is provided a superconducting circuit. The superconducting circuit may comprise a first chip, the first chip may comprise a superconducting device layer, where the superconducting device layer is a portion of a first surface of the first chip and includes at least a portion of at least one superconducting device. The superconducting circuit may comprise a second chip, and the second chip may comprise: a multi-layer control stack comprising at least a plurality of superconducting wiring layers, the plurality of superconducting wiring layers operable to provide at least one superconducting device control circuit including at least one communicative interface on a first portion of a first surface of the second chip, and a superconductive shield layer overlying a portion of the multi-layer control stack to occupy a second portion of the first surface of the second chip. The first chip and the second chip may be communicatively coupled with the first surfaces of the first chip and the second chip facing one another and with a space or a gap to maintain a physical distance between the superconducting device layer and the first surface of the second chip, and the space or the gap may consist of at least one of: air, a vacuum, and a partial vacuum. The superconducting device layer and the first surface of the second chip are non-galvanically coupled. A combination of the superconductive shield layer and the space or the gap reduces magnetic and electrical interference between superconducting devices in the superconducting device layer.

In an implementation, there is provided a superconducting circuit. The superconducting circuit may comprise: a first chip, the first chip may comprise a superconducting device layer, where the superconducting device layer is a portion of a first surface of the first chip and includes at least a portion of at least one superconducting device; and a second chip, the second chip may comprise: a multi-layer control stack that may comprise at least one superconducting device control circuit that may include at least one communicative interface, where the at least one communicative interface may be located on a first portion of a first surface of the second chip, and a superconductive shield layer overlying a portion of the multi-layer control stack, and occupying a second portion of the first surface of the second chip. The first portion of the first surface of the second chip may be located on an external surface of a trench in the second chip, the trench consisting of at least one of: air, a vacuum, and a partial vacuum. A second portion of the first surface of the first chip and the second portion of the first surface of the second chip may be communicatively coupled to one another such that the superconducting device layer and the at least one communicative interface may be separated by a depth of the trench and at least partially surrounded by side walls of the trench. A combination of the superconductive shield layer and the space or the gap may reduce magnetic and electrical interference between superconducting devices in the superconducting device layer.

In other implementations, the features described above may be combined together in any reasonable combination as will be recognized by those skilled in the art.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not necessarily drawn to scale, and some of these elements are arbitrarily enlarged and positioned to improve drawing legibility. Further, the particular shapes of the elements as drawn, are not necessarily intended to convey any information regarding the actual shape of the particular elements, and have been solely selected for ease of recognition in the drawings.

FIG. 1 is a schematic diagram of a hybrid computing system including a digital computer coupled to an analog computer, in accordance with the present systems, devices, and methods.

FIG. 2A is a schematic diagram of a circuit of an example superconducting quantum processor, in accordance with the present systems, devices, and methods.

FIG. 2B is a block diagram of a portion of an example superconducting quantum processor, in accordance with the present systems, devices, and methods.

FIG. 3 is a cross-sectional view of a portion of multi-layer fabrication stack of an example implementation of a superconducting integrated circuit, in accordance with the present systems, devices, and methods.

FIG. 4 is a cross-sectional view of a superconducting integrated circuit including a main chip and a shield flip chip, in accordance with the present systems, devices, and methods.

FIG. 5 is a cross-sectional view of a superconducting integrated circuit including a main chip, a shield flip chip, and grounding bump bonds, in accordance with the present systems, devices, and methods.

FIG. 6A is a cross-sectional view of a superconducting integrated circuit including a main chip and a shield flip chip having a trench, the shield flip chip positioned to be mounted to the main chip, in accordance with the present systems, devices, and methods.

FIG. 6B is a cross-sectional view of a superconducting integrated circuit including in which the shield flip chip of FIG. 6A is mounted to the main chip of FIG. 6A in a flip chip arrangement, in accordance with the present systems, devices, and methods.

FIG. 7A is a cross-sectional view of a superconducting integrated circuit including a qubit chip and a control flip chip having a trench, where the control flip chip positioned to be mounted to the main chip, in accordance with the present systems, devices, and methods.

FIG. 7B is a cross-sectional view of a superconducting integrated circuit including in which the control flip chip of FIG. 7A is mounted to the main chip of FIG. 7A in a flip chip arrangement, in accordance with the present systems, devices, and methods

FIG. 8 is a cross-sectional view of a superconducting integrated circuit including a qubit chip and a control flip chip, in accordance with the present systems, devices, and methods.

FIG. 9 is a cross-sectional view of a superconducting integrated circuit including a high-coherence qubit circuit and a multi-layer control circuit formed on opposing sides of a single chip, in accordance with the present systems, devices, and methods.

FIG. 10 is a flowchart illustrating a method to fabricate a superconducting integrated circuit having a flip-chip configuration for high coherence, in accordance with the present systems, devices, and methods.

FIG. 11 is a flowchart illustrating another method to fabricate a superconducting integrated circuit having a flip-chip configuration for high coherence, in accordance with the present systems, devices, and methods.

### DETAILED DESCRIPTION

### Preamble

In the following description, some specific details are included to provide a thorough understanding of various disclosed implementations and embodiments. One skilled in the relevant art, however, will recognize that embodiments may be practiced without one or more of these specific details, or with other methods, components, materials, etc. In other instances, well-known structures associated with superconducting devices, integrated superconducting circuits, and fabrication equipment, have not been shown or described in detail to avoid unnecessarily obscuring descriptions of the implementations or embodiments of the present methods. Throughout this specification and the appended claims, the words “element” and “elements” are used to encompass, but are not limited to, all such structures, systems, and devices associated with superconductive circuits and integrated superconductive circuits.

Unless the context requires otherwise, throughout the specification and claims which follow, the word “comprise” is synonymous with “including,” and is inclusive or open-ended (i.e., does not exclude additional, unrecited elements or acts).

Reference throughout this specification to “one embodiment” “an embodiment”, “another embodiment”, “one example”, “an example”, “another example”, “one implementation”, “another implementation”, or the like means that a particular referent feature, structure, or characteristic described in connection with the embodiment, example, or implementation is included in at least one embodiment, example, or implementation. Thus, the appearances of the phrases “in one embodiment”, “in an embodiment”, “another embodiment” or the like in various places throughout this specification are not necessarily all referring to the same embodiment, example, or implementation. Furthermore, the particular features, structures, or characteristics may be combined in any suitable manner in one or more embodiments, examples, or implementations.

It should be noted that, as used in this specification and the appended claims, the singular forms “a,” “an,” and “the” include plural referents unless the content clearly dictates otherwise. Thus, for example, reference to a circuit including “a device” includes a single device, or two or more devices. It should also be noted that the term “or” is generally employed in its sense including “and/or” unless the content clearly dictates otherwise.

In the descriptions of the superconducting circuits herein, the term “layer” can herein refer to a material having a thickness, where at least a portion of the material is in contact with at least a portion of an additional surface. In some implementations, at least a portion of a layer may fill in gaps between portions of a preceding layer (for instance, due to patterning of the preceding layer). Thus, while referred to as layers, two or more denominated layers can reside on a same level or plane or a common level or common plane spaced along a cross-section of a superconducting circuit.

In the descriptions of the superconducting circuits herein, the terms: “overlie” and “overlying” refers to a layer either directly or indirectly overlying a referenced layer. The term “directly overlying” a referenced layer refers to the layer being formed directly on at least a portion of the referenced layer without an intervening layer. The term “indirectly overlying” a layer refers to the layer being formed over at least a portion of the referenced layer, with at least one intervening layer between the referenced layer and the layer. While such assumes a particular orientation of the superconducting circuits, this is not intended to be limiting. Thus, the orientations of the superconducting as illustrated in the figures can be flipped upside down, for example.

Herein, “galvanic” coupling can refer to electrical coupling in which the coupled structures and/or devices share a common length of metal, and “direct galvanic coupling” can refer to galvanic coupling for which there are no interleaving metal layers between the coupled structures and/or devices.

The headings provided herein are for convenience only and do not interpret the scope or meaning of the embodiments.

### Example Computing System

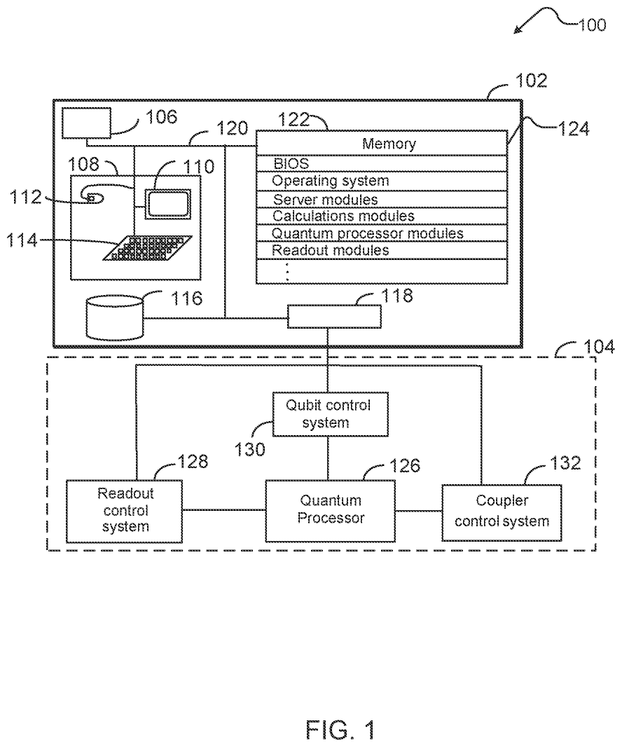

FIG. 1 illustrates a computing system 100 comprising a digital computer 102. The example digital computer 102 includes one or more digital processors 106 that may be used to perform classical digital processing tasks. Digital computer 102 may further include at least one system memory 122, and at least one system bus 120 that couples various system components, including system memory 122 to digital processor(s) 106. System memory 122 may store one or more sets of processor-executable instructions, which may be referred to as modules 124.

The digital processor(s) 106 may be any logic processing unit or circuitry (for example, integrated circuits), such as one or more central processing units (“CPUs”), graphics processing units (“GPUs”), digital signal processors (“DSPs”), application-specific integrated circuits (“ASICs”), programmable gate arrays (“FPGAs”), programmable logic controllers (“PLCs”), etc., and/or combinations of the same.

In some implementations, computing system 100 comprises an analog computer 104, which may include one or more quantum processors 126. Quantum processor 126 may include at least one superconducting integrated circuit fabricated using systems and methods described in the present application. Digital computer 102 may communicate with analog computer 104 via, for instance, a controller 118. Certain computations may be performed by analog computer 104 at the instruction of digital computer 102.

Digital computer 102 may include a user input/output subsystem 108. In some implementations, the user input/output subsystem includes one or more user input/output components such as a display 110, a mouse 112, and/or a keyboard 114.

System bus 120 may employ any known bus structures or architectures, including a memory bus with a memory controller, a peripheral bus, and a local bus. System memory 122 may include non-volatile memory, such as read-only memory (“ROM”), static random-access memory (“SRAM”), Flash NAND; and volatile memory such as random-access memory (“RAM”) (not shown).

Digital computer 102 may also include other non-transitory computer- or processor-readable storage media or non-volatile memory 116. Non-volatile memory 116 may take a variety of forms, including: a hard disk drive for reading from and writing to a hard disk (for example, a magnetic disk), an optical disk drive for reading from and writing to removable optical disks, and/or a solid state drive (SSD) for reading from and writing to solid state media (for example NAND-based Flash memory). Non-volatile memory 116 may communicate with digital processor(s) via system bus 120 and may include appropriate interfaces or controllers 118 coupled to system bus 120. Non-volatile memory 116 may serve as long-term storage for processor- or computer-readable instructions, data structures, or other data (sometimes called program modules or modules 124) for digital computer 102.

Although digital computer 102 has been described as employing hard disks, optical disks and/or solid-state storage media, those skilled in the relevant art will appreciate that other types of non-transitory and non-volatile computer-readable media may be employed. Those skilled in the relevant art will appreciate that some computer architectures employ non-transitory volatile memory and non-transitory non-volatile memory. For example, data in volatile memory may be cached to non-volatile memory, or a solid-state disk that employs integrated circuits to provide non-volatile memory.

Various processor-readable or computer-readable and/or executable instructions, data structures, or other data may be stored in system memory 122. For example, system memory 122 may store instructions for communicating with remote clients and scheduling use of resources including resources on digital computer 102 and analog computer 104. Also, for example, system memory 122 may store at least one of processor executable instructions or data that, when executed by at least one processor, causes the at least one processor to execute the various algorithms to execute instructions. In some implementations system memory 122 may store processor- or computer-readable calculation instructions and/or data to perform pre-processing, co-processing, and post-processing to analog computer 104. System memory 122 may store a set of analog computer interface instructions to interact with analog computer 104.

Analog computer 104 may include at least one analog processor such as quantum processor 126. Analog computer 104 may be provided in an isolated environment, for example, in an isolated environment that shields the internal elements of the quantum computer from heat, magnetic field, and other external noise. The isolated environment may include a refrigerator, for instance a dilution refrigerator, operable to cryogenically cool the analog processor, for example to temperature below approximately 1 K.

Quantum processors may perform two general types of quantum computation. The first, quantum annealing and/or adiabatic quantum computation, generally relies on the physical evolution of a quantum system. Gate, or circuit, model quantum computation relies on the use of quantum gate operations to perform computations with data. Surface code refers to a particular implementation of error-corrected gate or circuit quantum computation (QC), wherein logical qubits are encoded into portions or patches of a square lattice of physical qubits using a two-dimensional low density parity check scheme. Other implementations of gate model quantum computation are known in the art.

Analog computer 104 may include programmable elements such as qubits, couplers, and other devices (also referred to herein as controllable devices). Qubits may be read out via a readout control system 128. Readout results may be sent to other computer- or processor-readable instructions of digital computer 102. Qubits may be controlled via a qubit control system 130. Qubit control system 130 may include on-chip Digital to Analog Converters (DACs) and analog lines that are operable to apply a bias to a target device. Couplers that couple qubits may be controlled via a coupler control system 132. Coupler control system 132 may include tuning elements such as on-chip DACs and analog lines. In some implementations, qubit control system 130 and coupler control system 132 may be used to implement a quantum annealing schedule on analog computer 104 or program qubits and/or couplers of quantum processor 126.

Programmable elements may be included in quantum processor 126 in the form of an integrated circuit. Qubits and couplers may be positioned in layers of the integrated circuit that comprise a first material. Other devices, such as readout control system 128, may be positioned in other layers of the integrated circuit that comprise a second material. The programmable elements and/or quantum processor can advantageously include the various superconducting integrated circuits having flip-chip arrangements with high coherence devices as described herein.

### Superconducting Quantum Processor

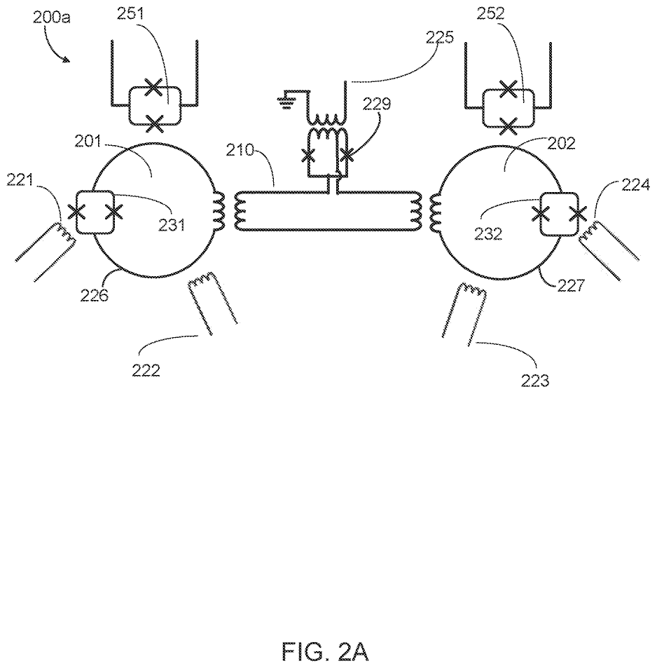

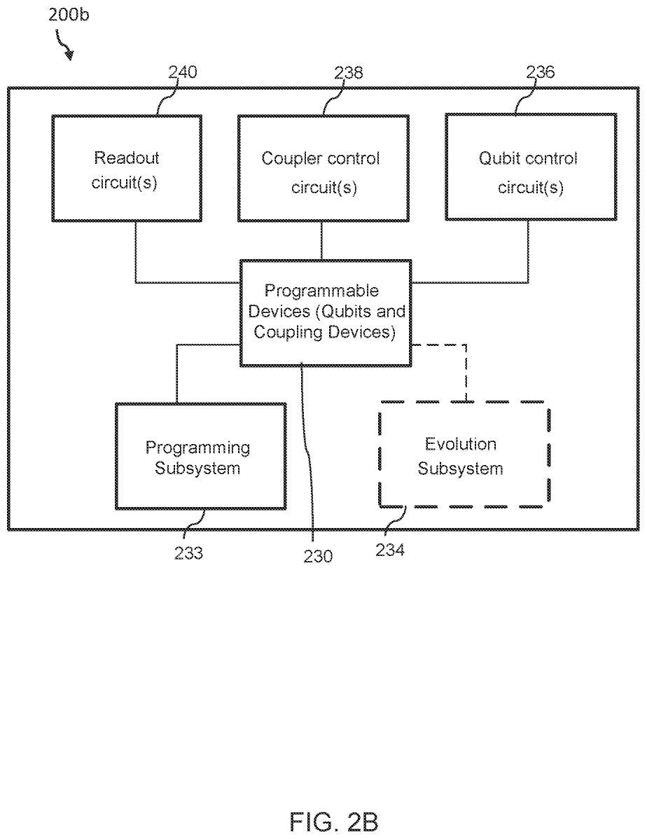

FIG. 2A is a schematic diagram of a circuit 200a of an example superconducting quantum processor, according to at least one implementation. In some implementations, the superconducting quantum processor of circuit 200a may be analog computer 104 shown in FIG. 1. Circuit 200a includes two superconducting qubits 201 and 202. Also shown is a tunable coupling (diagonal coupling) via a coupler 210 between qubits 201 and 202 (i.e., providing 2-local interaction). While circuit 200a shown in FIG. 2A includes only two qubits 201, 202 and one coupler 210, those of skill in the art will appreciate that a superconducting quantum processor may include any number of qubits and any number of couplers coupling information between them.

Circuit 200a includes a plurality of interfaces 221, 222, 223, 225, and 225 that are used to configure and control the state of the superconducting quantum processor. Each of interfaces 221, 222, 223, 224, 225 may be realized by a respective inductive coupling structure, as illustrated, as part of a programming subsystem and/or an optional evolution subsystem. Alternatively, or in addition, interfaces 221, 222, 223, 224, 225 may be realized by a galvanic coupling structure. In some implementations, one or more of interfaces 221, 222, 223, 224, 225 may be driven by one or more flux storage devices or Digital-to-Analog Converters (DACs). Such a programming subsystem and/or optional evolution subsystem may be separate from the superconducting quantum processor, or may be included locally (i.e., on-chip with the superconducting quantum processor). For example, referring to computing system 100 of FIG. 1, locally included programming subsystem and/or optional evolution subsystem can be arranged as part of analog computer 104.

In the operation of the superconducting quantum processor, interfaces 221 and 224 may each be used to couple a flux signal into a respective Josephson junctions 231 and 232, respectively, of qubits 201 and 202. In some implementations, such as in circuit 200a of FIG. 2A, Josephson junctions 231, 232 are compound Josephson junctions (CJJs). In other implementations, Josephson junctions 231, 232 can be compound-compound Josephson junctions (CCJJs).

Similarly, interfaces 222 and 223 may each be used to apply a flux signal into respective superconducting loops 226 and 227 of qubits 201 and 202.

Furthermore, interface 225 may be used to couple a flux signal into coupler 210. Coupler 210 includes a Josephson junction 229, which, in some implementations, can be a CJJ or a CJJ.

Superconducting loops 226, 227 and Josephson junctions 231, 232 of qubits 201, 202, as well as coupler 210, can comprise a material that exhibits superconducting behavior at and below a critical temperature.

Throughout this specification and the appended claims, the term “quantum processor” is used to generally describe a collection of physical qubits (e.g., qubits 201 and 202) and qubit couplers (e.g., coupler 210). The physical qubits 201 and 202 and coupler 210 are referred to as the “controllable devices” of a quantum processor and their corresponding parameters are referred to as the “controllable parameters” of the quantum processor. In the context of a quantum processor, the term “programming subsystem” is used to generally describe the interfaces (e.g., “programming interfaces” 222, 223, and 225) used to apply the controllable parameters to the controllable devices of the superconducting quantum processor and other associated control circuitry and/or instructions. In some implementations, programming interfaces 222, 223, and 225 may include DACs. DACs may also be considered programmable devices that are used to control controllable devices such as qubits, couplers, and parameter tuning devices.

As previously described, the programming interfaces of the programming subsystem may communicate with other subsystems which may be separate from the quantum processor or may be included locally on the processor, such as arranged as part of analog computer 104 of FIG. 1. The programming subsystem may be configured to receive programming instructions in a machine language of the quantum processor and execute the programming instructions to program the programmable and controllable devices in accordance with the programming instructions. In some implementations, where the quantum processor is implemented as analog computer 104 of FIG. 1, the controllable devices may be arranged as part of quantum processor 126 and these other subsystems may be at least one of: readout control system 128, qubit control system 130, and coupler control system 132 of analog computer 104. The initial programming instructions may be provided using digital computer 102 and sent to the quantum processor and its corresponding subsystems through digital processor(s) 106.

Circuit 200a also includes readout devices 251 and 252, in which readout device 251 is associated with qubit 201 and readout device 252 is associated with qubit 202. In the example implementation shown in FIG. 2A, each of readout devices 251 and 252 includes a direct current superconducting quantum interference device (DC-SQUID) inductively coupled to the corresponding qubit. In the context of circuit 200a, the term “readout subsystem” is used to generally describe the readout devices 251, 252 used to read out the final states of the qubits (e.g., qubits 201 and 202) in the superconducting quantum processor to produce a bit string. The readout subsystem may also include other elements, such as routing circuitry (e.g., latching elements, a shift register, or a multiplexer circuit) and/or may be arranged in alternative configurations (e.g., an XY-addressable array, an XYZ-addressable array, etc.), any of which may comprise DACs. Qubit readout may also be performed using alternative circuits, such as that described in U.S. Pat. No. 8,854,074. The behavior of the readout subsystem may be informed by signals transmitted from readout control system 128 in FIG. 1. Readout control system 128 may be coupled to readout devices 251 and 252 via DACs, analog lines, or other suitable means, While FIG. 2A illustrates only two physical qubits 201, 202, one coupler 210, and two readout devices 251, 252, a quantum processor (e.g., processor comprising circuit 200a) may employ any number of qubits, couplers, and/or readout devices, including a larger number (e.g., hundreds, thousands or more) of qubits, couplers and/or readout devices. The application of the teachings herein to processors with a different (e.g., larger) number of computational components should be readily apparent to those of ordinary skill in the art.

A superconducting quantum processor may include other types of qubits besides superconducting flux qubits. For example, a superconducting quantum processor may include superconducting charge qubits, transmon qubits, and the like. A superconducting qubit may include a shunt capacitor. Examples of qubits that use a shunt capacitor include a three-junction flux qubit, a zero-pi qubit, a fluxonium qubit, a bifluxon qubit, and a transmon. Approaches described in the present application can be applied generally to any of the above-noted types of qubits, as well as to similar qubits as are known in the art.

FIG. 2B is a block diagram of a portion 200b of an example superconducting quantum processor, according to the present disclosure. Portion 200b of the superconducting quantum processor includes programmable devices 230. Programmable devices 230 includes a collection of qubits and coupling devices. Each coupling device is operable to communicatively couple two or more qubits, an example of which is described above with reference to FIG. 2A.

Portion 200b of the superconducting quantum processor also includes: a programming subsystem 233, an optional evolution subsystem 234 (described above with reference to FIG. 2A), a qubit control circuit(s) 236, a coupler control circuit(s) 238, and a readout circuit(s) 240.

FIG. 2B shows that each of programming subsystem 233, qubit control circuit(s) 236, coupler control circuit(s) 238, readout circuit(s) 240, and optional evolution subsystem 234 are arranged in communication with programmable devices 230. However, this is only an example and not intended to be limiting. In some implementations, programmable devices 230 can optionally not be communicatively coupled to all of subsystems 233, 234 and circuits 236, 238, 240, and/or programmable devices 230 may be coupled to one or more of these elements via one or more intermediary structure that are not shown as part of portion 200b. In some implementations, any of subsystems 233, 234 and circuits 236, 238, 240 can optionally be communicatively coupled to one another and/or intermediary structures.

Like circuit 200a described with reference to FIG. 2A, the example superconducting quantum processor of FIG. 2B may be implemented as quantum processor 126 of FIG. 1. Each of the elements in portion 200b of the superconducting quantum processor (230, 233, 234, 236, 238, 240) can be located within quantum processor 126, and can be arranged in communication with one or more of: digital processor(s) 106 of digital computer 102, and readout control system 128, qubit control system 130, and coupler control system 132 of analog computer 104.

In some implementations, circuit 200a and portion 200b of the superconducting processor can optionally be all or a portion of a superconducting processor used for quantum annealing and/or adiabatic quantum computing. In such implementations, plurality of interfaces 221, 222, 223, 224, 225 couple respective flux signals into qubits 201, 202 to realize parameters of the system Hamiltonian. For instance, the coupling of interfaces 221, 224 to qubits 201, 202 may provide a tunable tunneling term (the 4; term), and the coupling may provide the off-diagonal ox terms of the system Hamiltonian. The use of interfaces 222, 223 to apply a flux signal into superconducting loops 226, 227 of qubits 201, 202 may realize the hᵢ terms (dimensionless local fields for the qubits), and the coupling may provide the diagonal oz terms in the system Hamiltonian. Lastly, interface 225 may be used to couple a flux signal into coupler 210, thereby realizing the Jij term(s) (dimensionless local fields for the couplers), for which the coupling may provide the diagonal of oz terms in the system Hamiltonian. Examples of Hamiltonians (and their terms) used in quantum computing are described in greater detail in, for example, U.S. Pat. No. 9,424,526. In such implementations, parameters of the system Hamiltonian may be considered “controllable parameters” of the quantum processor.

In implementations where circuit 200a and portion 200b are all or a portion of a superconducting processor used for quantum annealing and/or adiabatic quantum computing, portion 200b of the example superconducting quantum processor may include evolution subsystem 234. Evolution subsystem 234 may include the interfaces (e.g., “evolution interfaces” 221, 224) used to evolve devices such as qubits 201, 202 of circuit 200a and other associated control circuitry and/or instructions. For example, the evolution subsystem may include annealing signal lines and their corresponding interfaces (221, 224) to couple signals to the qubits (201, 202).

In other implementations, circuit 200a and portion 200b of the superconducting processor can optionally be all or a portion of a superconducting processor used for gate-model quantum computing.

### Multi-Layer Fabrication Stack of Superconducting Quantum Processor

As described above, a superconducting circuit, which may be used as analog computer 104 or quantum processor 126 of FIG. 1 or quantum processor of FIGS. 2A and 2B, may include several structures and devices. The superconducting circuit may be used within a system in which it is arranged at a particular location within a cryogenic environment. Examples of technologies providing cryogenic environments are described in: U.S. Pat. Nos. 9,134,047 and 10,378,803, and U.S. Patent Application Publication No. 2020/0054961. The intended arrangement may inform design specifications of superconducting circuit, such as space limitations and behavior of materials of circuit components. Limiting the amount of space occupied by the superconducting circuit may be advantageous, such that there is room to include all desired structures and devices on-chip.

The complexity of problems that can be solved on a quantum processor may be proportional to its number of qubits, couplers, and associated devices. Therefore, the superconducting circuit used to provide a quantum processor for solving complex problems can ideally be scaled to accommodate a large number of devices. Particularly, it may be desirable for a superconducting circuit to include a significantly greater number of devices than the state-of-the-art quantum processors that have a relatively small number of qubits.

To address size and scalability concerns, it may be advantageous to implement a superconducting circuit including a quantum processor using a multi-layer fabrication stack. A multi-layer fabrication stack enables a vertical build-up of its devices and structures, which may allow for a reduction in the overall footprint of the quantum processor. Herein, the term: “footprint” is used to refer to an occupied area in an x-y plane. In some implementations, reduction of the footprint of the quantum processor may allow for controllable devices, such as qubits and couplers, to have shorter wiring loops. This may beneficially allow for the quantum processor to operate at a higher energy scale.

In some implementations in which the superconducting circuit has strict footprint limitations, use of a multi-layer fabrication stack can allow for more devices and structures to be included on-chip. This may advantageously enable the quantum processor to solve more complex problems than a single-layer fabrication stack of a superconducting circuit having the same footprint. As well, the use of vertical space allows for inclusion of other structures as part of the superconducting circuit that might improve the operation of the quantum processor. For example, structures such as capacitance or inductance tuners may provide greater homogenization of qubit properties, resulting in more accurate solutions.

Use of a multi-layer fabrication stack may reduce degradation of signals transmitted between qubits and other structures of the quantum processor. For example, a multi-layer fabrication stack may include programmable devices 230 of FIG. 2B that may communicate with some or all of subsystems 233, 234 and circuits 240, 238, 236. In an implementation in which portion 200b of the superconducting circuit is implemented as a multi-layer fabrication stack, signals between programmable devices 230 and the other components (233, 234, 236, 238, 240) may be carried by internal wiring that is not exposed to the external environment, and may travel a shorter distance than might otherwise be required. Resultantly, less environmental noise may be introduced to the signals that might interfere with operation of the quantum processor. The multi-layer fabrication stack can also be designed to include materials that may limit undesirable effects of noise, as well as to shield particular devices to provide electrical and/or magnetic isolation.

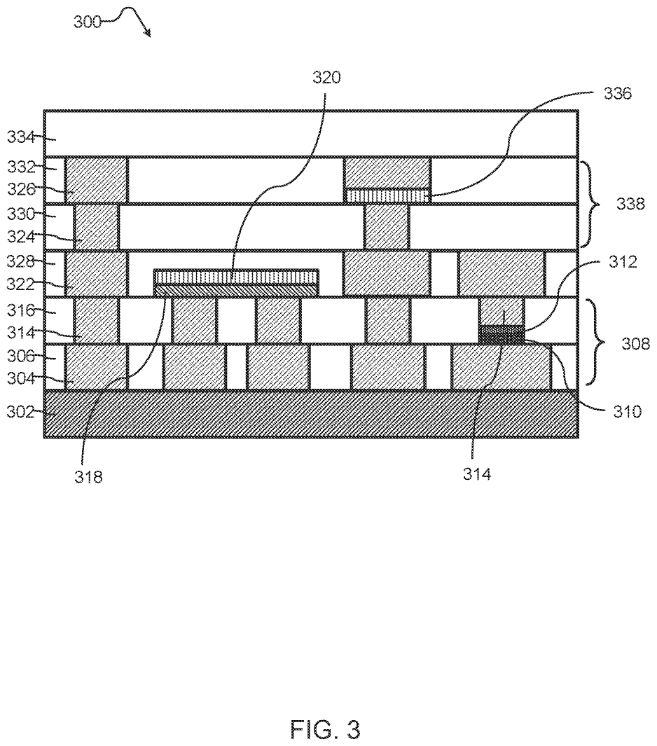

FIG. 3 is a cross-sectional view of a portion 300 of a multi-layer fabrication stack of an example superconducting integrated circuit. In some implementations, portion 300 of the multi-layer fabrication stack implements at least a portion of quantum processor 126 of FIG. 1 and/or the example superconducting quantum processor of FIG. 2. As explained below, portion 300 includes: multiple metal layers (e.g., wiring layers) and dielectric layers, vias (vertical interconnect accesses), a Josephson junction, a capacitor, and a kinetic inductor (used, for example, in a flux storage device). It will be understood that portion 300 of FIG. 3 is a simplified view of a multi-layer fabrication stack, and, for clarity of presentation, the features are not shown to scale.

Portion 300 includes: a substrate 302, a first superconducting metal layer 304 that overlies at least a portion of substrate 302, and a first dielectric layer 306 that overlies at least a portion of substrate 302. As illustrated in FIG. 3, first superconducting metal layer 304 may be etched, with first dielectric layer 306 filling in the gaps between portions of first superconducting metal layer 304. Thus, while referred to as layers, two or more denominated layers can reside on a same level, plane or a common level or plane spaced over substrate 302. A “layer” can herein refer to a material having a thickness, where at least a portion of the material is in contact with at least a portion of an additional surface. In some implementations, substrate 302 comprises one of: sapphire, quartz, silicon, silicon dioxide, and silicon nitride. In some implementations, first superconducting metal layer 304 comprises: niobium, aluminum, tantalum, and/or aluminum alloys. In some implementations, first dielectric layer 306 comprises: silicon dioxide (SiO₂) or silicon nitride (SIN). In some implementations, first dielectric layer 306 is polished (e.g., by chemical mechanical polishing) back to an upper surface of first superconducting metal layer 304.

Portion 300 further includes a Josephson junction 308 formed by a tri-layer that includes first superconducting metal layer 304 (also referred to in the present application as a base electrode of Josephson junction 308), a junction superconducting metal layer 310, a metal oxide 312 formed on junction superconducting metal layer 310, and a portion of a second superconducting metal layer 314 (also referred to in the present application as a counter-electrode of Josephson junction 308). Portion 300 further includes a second dielectric layer 316 overlaying at least a portion of first dielectric layer 306 and first superconducting metal layer 304. Similar to above, second superconducting metal layer 314 can be etched, and second dielectric layer 316 can reside in a same level or plane or common level or plane as second superconducting metal layer 314, spaced over first dielectric layer 306 and first superconducting metal layer 304.

Portion 300 includes a kinetic inductor 318 formed in a layer of material having a high kinetic inductance. The layer of high kinetic inductance material is also referred to in the present application as a flux storage layer. Patterning the high kinetic inductance layer to form kinetic inductor 318 can include masking and etching at least a portion of the high kinetic inductance layer. In some implementations, kinetic inductor 318 comprises titanium nitride (TiN). In some implementations, kinetic inductor 318 comprises niobium nitride (NbN). In some implementations, kinetic inductor 318 has a thickness of approximately 50 nm. In some implementations, kinetic inductor 318 is capped by a dielectric 320, e.g., silicon nitride (SiN). Dielectric 320 may act as a passivating and/or insulating layer to protect kinetic inductor 318.

Portion 300 further includes a third superconducting metal layer 322, a fourth superconducting metal layer 324, and a fifth superconducting metal layer 326. Third, fourth, and fifth superconducting metal layers 322, 324, and 326 may be superconducting wiring layers patterned to provide one or more superconducting traces, and/or metal layers patterned to provide one or more stud vias (vertical interconnect accesses).

Each superconducting metal layer 304, 314, 322, 324, and 326 may each be comprised of a same superconducting material or different superconducting materials as one or more of another, and each superconducting material exhibits superconducting behavior at and below a respective critical temperature. The critical temperature is a physical property of the particular composition of the material. Portion 300 of the multi-layer fabrication stack may be located in a cryogenic environment, and arranged to be in a region having a temperature where superconducting metal layers 304, 314, 322, 324, and 326 exhibit superconducting behavior. Superconducting metal layers 314, 322, 324, and 326 may comprise at least one of: niobium, aluminum, and tantalum.

Third, fourth, and fifth superconducting metal layers 322, 324, and 326 may be used to implement a plurality of different structures and/or devices within the fabrication stack. For example, one or more of superconducting metal layers 322, 324, 326 can optionally form at least portions of controllable devices, including: qubits, couplers, parameter tuning devices, and readout devices, as described above with respect to FIG. 2B.

In some implementations, the controllable device is a noise-susceptible superconducting device, which may refer to a programmable device that, if exposed to a threshold amount of noise, may result in a quantum processor producing inaccurate or suboptimal solutions to a problem. For example, qubits 201, 202 and coupler 210 of circuit 200a may be considered noise-susceptible devices because exposure of these devices to noise may interfere with the accuracy of the quantum data. It is noted that the term: “noise-susceptible” or “susceptible to noise” does not necessarily suggest that the device itself is physically more or less sensitive to noise compared to other devices that are not described as noise-susceptible. Sensitivities to processor performance are higher in noise-susceptible devices relative to devices that are described as less susceptible to noise.

As another example, at least one of third, fourth, and fifth superconducting metal layers 322, 324, and 326 can optionally form at least a portion of at least one DAC, which may comprise a loop of superconducting material interrupted by at least one Josephson junction. The at least one DAC may be used to implement a portion of a larger structure, including any one of subsystems 233, 234 or circuits 236, 238, 240 of portion 200b of the superconducting quantum processor of FIG. 2B. Portion 300 further includes third, fourth, fifth, and sixth dielectric layers 328, 330, 332, and 334, which may comprise silicon dioxide, and may be planarized by chemical mechanical polishing, for example.

Third, fourth, and fifth dielectric layers 328, 330, and 332 may exist within same layers (e.g., at a same level in a fabrication stack) as third, fourth, and fifth superconducting metal layers 322, 324, and 326, respectively. For instance, fifth dielectric layer 332 may be located on a same layer as fifth superconducting metal layer 326, and a portion of fifth dielectric layer 332 and/or fifth superconducting metal layer 326 overlie a portion of fourth dielectric layer 330. Fifth superconducting metal layer 326 may be etched such that fifth dielectric layer 332 fills in the gaps between portions of fifth superconducting metal layer 326.

Portion 300 includes a dielectric 336 patterned to form a dielectric portion of a parallel plate capacitor 338. Dielectric 336 may comprise SiN, and/or may have a thickness of 50 nm to 70 nm.

While FIG. 3 illustrates one fabrication stack of a superconducting integrated circuit having an arrangement of layers and devices, other implementations can include layers and devices in various different arrangements.

For instance, in some implementations, a multi-layer fabrication stack of a superconducting integrated circuit can include one or more layers that provide electrical and/or magnetic shielding, which hereinafter may be referred to as “shield layers”. Shield layers may reduce cross-talk and noise between devices or signals carried by conducting metal layers. Though not illustrated, shield layers may be included to indirectly or directly cover at least a portion of one or more superconducting devices or a portion of one or more superconducting metal layers, such that each shield layer extends along a surface thereof. The inclusion of one or more shield layers may be determined as needed by the particular application of the superconducting integrated circuit. In some implementations, a shield layer may comprise a same material as an adjacent superconducting metal layer, such as one or more of third, fourth, and fifth superconducting metal layers 322, 324, and 326. For instance, the material comprising a shield layer and its adjacent superconducting metal layer may be: niobium, aluminum, or tantalum. Further information on superconductive shields for use in a superconducting circuit can be found in U.S. Pat. No. 7,687,938.

### Flip-Chip Arrangement for High-Coherence Superconducting Integrated Circuit

Coherence exists when there is a definite phase relation between different states of qubits within a quantum processor, and allows for computation of quantum information encoded in quantum states of the qubits. Upon interaction between qubits and their environment, qubits may lose this quantum information after decohering in a thermodynamically irreversible manner following a decoherence time.

It can be desirable to fabricate qubits with decoherence times on the order of 1 μs. To achieve decoherence times on the order of 1 μs, qubits can be fabricated on integrated circuits having dielectrics with loss tangents less than 10⁻⁶. Suitable electrically insulating materials with a sufficiently low loss tangent include single-crystal silicon (Si) and sapphire. Dielectrics typically used in superconducting integrated circuits (e.g., a dielectric used as an insulating layer) have larger loss tangents. Use of dielectrics having larger loss tangents larger than 10⁻⁶ can be an obstacle to achieving qubits with decoherence times on the order of 1 μs.

In implementations in which the quantum processor performs computations using adiabatic quantum computing and/or quantum annealing, decoherence may cause a transition from coherent to decoherent tunneling before the transition is induced by intrinsic phase transitions. This decoherence may limit a speed and/or accuracy with which the processor evolves and produces solutions.

In implementations in which the quantum processor performs computations using sequences of logical gates acting upon the qubits, significantly longer decoherence times may be particularly advantageous as compared to implementations using quantum annealing. For the processor to perform calculations, gate-model quantum computing includes a series of quantum error correction operations. Quantum error correction requires the qubits to be capable of maintaining quantum coherence over time periods on the order of 1000 times the single-gate time.

Environmental noise, and particularly flux noise, in a quantum processor may increase a rate at which qubits decohere. Undesirably short decoherence times may prevent the quantum processor from performing all desired computations before quantum information is lost.

The fabrication of high-coherence qubits has been demonstrated by patterning a single layer of low-loss superconducting metal including qubit circuitry on top of a low-noise, low-loss substrate. The lack of coupling interfaces and use of low-loss materials in the resulting circuit may greatly reduce noise affecting the qubit behavior and coherence-reducing interactions between qubits and their environment. However, as discussed both above and in further details below, the resulting single layer circuit may also have limited functionality and might not be able to provide a scalable quantum processor.

Without shielding, the qubits patterned on the single superconducting metal layer may suffer from cross-talk between one another, which may negatively impact the precision of quantum information.
As well, on-chip inclusion of a plurality of devices and/or structures within a quantum processor may allow for at least one or more of: parameter tuning of controllable devices; improved read-out and addressing of controllable devices; improved structures to control qubits, couplers, and other programmable devices; and, shield structures to prevent degradation of signals transmitted between any components within the superconducting circuit. With only one or two layers of low-noise superconducting metal, the quantum processor might not have the resources available to contain, program, and readout a number of qubits and couplers that can be used to solve complex problems.

In addition to the multi-layer fabrication stack discussed above, one way to provide a scalable, low-noise processor can be to form a fabrication stack of a superconducting circuit including more than one superconducting material to reduce the effects of flux noise. A low-noise material, such as aluminum, may be used in regions of an integrated circuit that include qubits and couplers for which reducing noise is particularly advantageous. A different superconducting material, having benefits in fabrication but less favorable noise properties, such as niobium, may be used in regions where noise reduction is desired but not as advantageous.

To reduce exposure of qubits and couplers to potential sources of noise, the fabrication stack of such superconducting circuits may be strategically ordered based on the noise susceptibility of devices formed in the respective layers. For example, the qubits and couplers may be arranged in a low-noise wiring region toward the bottom of the stack, while control circuitry may be arranged in a region closer to the top of the stack.

Multi-layered fabrication stacks having wiring layers of different superconducting material are further described in International Application Publication No. 2022/178130.

Low-loss and low-noise materials may be challenging to integrate into a multi-layer fabrication stack. In part, this is caused by transmission of undesirable noise originating from dielectric insulating layers to qubits across such dielectric-metal interfaces. Exposure of qubits to this noise may result in a shortened decoherence time due to the more rapid loss of quantum information to the environment.

One technique to mitigate some of the effects of dielectric-metal interfaces realized by the qubits can include providing an air gap or vacuum layer or space between a qubit layer and other circuitry within the fabrication stack of the superconducting circuit. However, fabrication of a multi-layer stack having such an internal air gap, vacuum layer, or space may be both expensive and technically difficult to achieve using conventional techniques and equipment.

To address this challenge, a flip-chip configuration to form a superconducting circuit may be employed. A main chip including the qubits and a flip chip including the remaining circuitry can be individually fabricated, and can then be arranged to be spaced apart by an air gap or vacuum layer. In some implementations, the qubits and couplers of the qubit chip are electrically coupled to control circuitry on the flip chip using bump bonds.

Both the cross-talk and the footprint associated with bump bonds may disadvantageously reduce a qubit density and thus a scalability of the quantum processor. For instance, unshielded flow of currents between the two chips across the bump bonds may lead to uncontrollable cross-talk between qubits. At a particular threshold, a reduction in circuit density may be required for the cross-talk not to overwhelm the desirable signal content. As well, since two bump bonds are typically used for each control line of a qubit circuit and a readout circuit, the geometric size of the bump bonds constrains a number of qubits that can be included in the superconducting circuit, and consequently a complexity of problems solvable thereon.

To provide a number of qubits capable of problem solving when faced with footprint limitations, a quantum processor may be designed having two or more chips that each include qubits. These two or more chips including qubits may be communicatively coupled to one another and/or additional devices within a quantum processor. The coupling structure between qubits may be referred to as “interconnects” that transmit information at a high speed. However, the low qubit density of such solutions may increase the complexity of high-speed interconnects over large distances, resulting in low operation speeds. Subsequently, operation speeds below a particular speed may result in more errors per error correction cycle of the quantum processor. As the quantum processor may have an operation speed slower than a decoherence time of its qubits, the resultant amount of quantum information lost from the qubits may result in more errors that require correction. This may detrimentally prevent the system from achieving a desired error correction threshold. One implementation of error correction of a quantum processor using surface code cycles is described in Litinski (Litinski, D., 2019, Quantum 3, 128, ISSN 2521-327X).

In order to provide a scalable superconducting processor including highly-coherent qubits, a superconducting integrated circuit can be fabricated to have a flip-chip configuration including: a main chip including a first portion of the superconducting integrated circuit; a flip chip including the remainder of the devices comprising the superconducting integrated circuit; and, an air gap or vacuum layer or space that separates at least a portion of the main chip from at least a portion of the flip chip.

While the terms: “main chip” and “flip chip” are used to ease understanding of the various embodiments, those terms are used in the relative sense as one chip or fabrication substrate is arranged in flip-chip configuration with respect to another chip or fabrication substrate, without regard to which particular chip or fabrication is nominally “face up” and which is nominally “face down”.

The first portion of the superconducting integrated circuit can include a plurality of noise-susceptible devices, such as qubits and couplers. The plurality of noise-susceptible devices can be arranged on the external surface of the main chip that faces the flip chip, but are not electrically coupled to the flip chip. Here, the non-electrical coupling may refer to a coupling that is not provided by direct electrical communication via a direct or indirect galvanic connection.

This flip-chip arrangement can advantageously be a superconducting integrated circuit that includes a multi-layer fabrication stack with devices and structures for providing a scalable quantum processor, as well as mechanisms for limiting noise that impacts the efficacy of qubits and other devices in the circuit. Fabrication of the high-coherence superconducting integrated circuit having the described flip-chip arrangement may favorably mitigate limitations of conventional fabrication technologies, particularly those relating to creation of air gaps or vacuum layers in an internal layer of a multi-layer fabrication stack.

### Shield Flip-Chip for High-Coherence Superconducting Integrated Circuit

As previously described, one challenge associated with some superconducting integrated circuits having high-coherence qubits is providing adequate shielding of the qubits. In order to address this limitation, a superconducting integrated circuit may have a flip-chip configuration in which the flip chip acts as a shield layer.

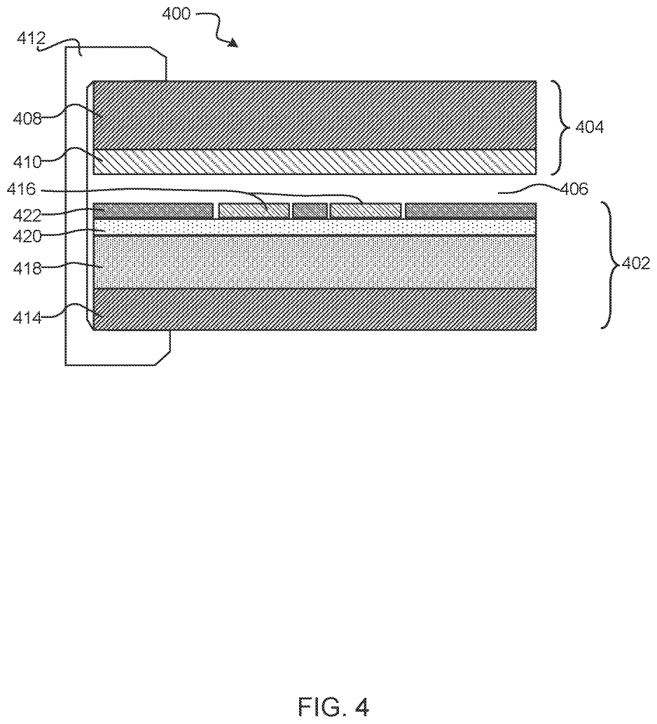

FIG. 4 is a cross-sectional view of a superconducting integrated circuit including a main chip and a shield flip chip. A superconducting circuit 400 shown in FIG. 4 can be all or at least a portion of quantum processor 126 of FIG. 1 and/or the quantum processor of FIGS. 2A and 2B. Superconducting circuit 400 includes a main chip 402 and a flip chip 404 that are spaced apart by one or more of: a space or a gap filled with air, a layer consisting of air, and a vacuum or partial vacuum layer, which is hereinafter referred to as: a separation space, gap, or layer 406. Main chip 402 and flip chip 404 are held in place by a mechanical coupler 412.

As used herein, overlie refers to a layer either directly or indirectly overlying a referenced layer. Directly overlying a referenced layer refers to the layer being formed directly on at least a portion of the referenced layer without an intervening layer. For each of superconducting circuits 400, 500, 600, 700, and 800 described herein, the relative position of layers formed on a particular chip are described with respect to the substrate of that chip. The substrate of the chip can be defined as its bottom later. This bottom layer is an external surface of one chip that does not oppose an external surface of the other chip when the two chips are arranged in a flip-chip configuration. As such, a first layer of a “flipped” chip that is described to overlie a second layer may appear relatively medial to the separation space, gap or layer of a superconducting circuit.

Flip chip 404 can act as a shield chip, and includes a layer of superconducting material to electrically and magnetically shield one or more noise-susceptible devices (also referred to as shield layer 410 herein) that directly overlies a substrate 408. Shield layer 410 is arranged on an external surface of flip chip 404, which, when superconducting circuit 400 is assembled, is adjacent to separation space, gap, or layer 406 and faces main chip 402. Shield layer 410 comprises a metal having a thickness and the metal is in physical contact with at least a portion of substrate 408. The metal may be a superconducting metal that exhibits superconducting behavior at and below a critical temperature, such as: aluminum, niobium, or tantalum. Shield layer 410 is not patterned to include any electrical traces, and does not carry any desired electrical signals used in the operation of a quantum processor. In some implementations, such as that shown in FIG. 4, shield layer 410 might not be in conductive and/or galvanic communication with any other components of superconducting circuit 400.

Main chip 402 includes: a substrate 414 arranged as an external layer of main chip 402; a multi-layer stack 418 directly overlying substrate 414; a low-loss insulating layer 420 directly overlying multi-layer stack 418; and, a noise-susceptible device wiring layer 416 directly overlying at least a portion of low-loss insulating layer 420. In some implementations, main chip 402 can optionally include a ground plane 422 on a same layer as noise-susceptible device wiring layer 416, but which is not in communication with noise-susceptible device wiring layer 416. Ground plane 422 also directly overlies a portion of low-loss insulating layer 420. In some implementations, ground plane 422 can optionally be a superconducting ground plane, and comprise a material that exhibits superconducting behavior at and below a critical temperature, such as: aluminum, niobium, and tantalum.

Main chip 402 may include, for example, a portion of a multi-layer fabrication stack such as portion 300 of FIG. 3. Substrate 414 of main chip 402 can comprise any suitable material, such as one of: silicon, sapphire, quartz, silicon dioxide, and silicon nitride. In some implementations, substrate 414 may comprise a high-resistivity, single-crystal silicon. Substrate 302 of portion 300 may be implemented as substrate 414 of superconducting circuit 400.

In some implementations, multi-layer stack 418 of main chip 402 can include some or all of layers 304 to 336 of portion 300 of the multi-layer fabrication stack of FIG. 3, as described above. Multi-layer stack 418 may also include additional layers that are not shown in portion 300, such as additional superconducting metal layers and shield layers. Multi-layer stack 418 may include without limitation, for example, some or all of the following: multiple metal layers (e.g., wiring layers) and interlayer dielectrics, vias (vertical interconnect accesses), Josephson junctions, and flux storage devices. Multi-layer stack 418 may also include, for example, devices that form: programming subsystem 233, readout circuit(s) 240, coupler control circuit(s) 238, and qubit control circuit(s) 236 of portion 200b of the quantum processor of FIG. 2B.

Noise-susceptible device wiring layer 416 can include portions of a plurality of programmable devices that, if exposed to an undesirable amount of noise, may result in a quantum processor producing inaccurate or suboptimal solutions to a problem. In some implementations, a plurality of qubits and couplers, for example, qubits 201, 202 and coupler 210 of circuit 200a, may be implemented as the plurality of noise-susceptible devices. The portions of qubits or couplers that form noise-susceptible device wiring layer 416 can include the superconducting loops of the devices, such as superconducting loops 226, 227 of qubits 201, 202. The superconducting loops may comprise a material that exhibits superconducting behavior at and below a critical temperature, and more particularly a low-noise superconducting material.

In some implementations, each portion of a device of the plurality of noise-susceptible devices of noise-susceptible device wiring layer 416 can optionally be an entire device of the plurality of noise-susceptible devices. For example, noise-susceptible device wiring layer 416 can optionally include the complete structures of one or more qubits and/or one or more couplers. For example, superconducting loops 226, 227 and Josephson junctions 231, 232 of qubits 201, 202 shown in circuit 200a can be arranged on a same layer. This can optionally be achieved through formation of Josephson junctions using double-angle evaporation fabrication techniques. However, this is not limiting, and other suitable low-noise fabrication techniques can alternatively be employed. For instance, single-layer Josephson junctions can optionally be formed in noise-susceptible device wiring layer using Dayem bridges. Single-layer Josephson junctions with Dayem bridges are described in International Patent Publication No. 2021/231224.

In some implementations, noise-susceptible device wiring layer 416 includes portions of noise-susceptible devices comprising a low-noise superconducting material. The low-noise superconducting material can optionally be aluminum, and the superconducting loops and other wiring of the plurality of noise-susceptible devices may comprise aluminum. In implementations in which Josephson junctions of the noise-susceptible devices are also formed within noise-susceptible device wiring layer 416, the metal layer(s) of the Josephson junction structures can also comprise aluminum.

Noise-susceptible device wiring layer 416 directly overlies low-loss insulating layer 420. Low-loss insulating layer 420 can beneficially comprise a material that has properties that may limit noise arising from the other layers and devices of multi-layer stack 418 from reaching noise-susceptible device wiring layer 416. In some implementations, low-loss insulating layer 420 can optionally be a high-resistivity, single-crystal silicon or sapphire.

Multi-layer stack 418 can include any of the remaining layer types, structures, and/or devices described above. In some implementations, the plurality of noise-susceptible devices can optionally have portions formed in both noise-susceptible device wiring layer 416 and multi-layer stack 418, which may be communicatively coupled across at least low-loss insulating layer 420.

For instance, multi-layer stack 418 may include qubit and/or coupler Josephson junctions that are coupled to respective superconducting loops of qubits and couplers in noise-susceptible device wiring layer 416. In some implementations, the Josephson junctions of the noise-susceptible devices can optionally be located at a layer of multi-layer stack 418 directly underlying low-loss insulating layer 420. In other implementations, the Josephson junctions of the noise-susceptible devices can optionally be located at a layer of multi-layer stack 418 located further away from noise-susceptible device wiring layer 416, such as a layer directly overlying substrate 414. In such arrangements, superconducting vias can be used to electrically couple portions of the plurality of noise-susceptible devices formed on noise-susceptible device wiring layer 416 with respective portions of the devices formed as part of multi-layer stack 418.

In some implementations that include optional ground plane 422, ground plane 422 and noise-susceptible device wiring layer 416 can be separated by an insulating material. The insulating material can optionally comprise a same material as low-loss insulating layer 420 or a different dielectric material. Optionally, the insulating material may belong to an extension of low-loss insulating layer 420. In alternative implementations, ground plane 422 and noise-susceptible device wiring layer 416 can be separated by spaces or gaps between these layers filled by air or a vacuum.

Flip chip 404 can be a chip that is fabricated independently of main chip 402, and then “flipped” relative to the order in which its layers are fabricated. Resultantly, an upper external surface of flip chip 404 faces an upper external surface of main chip 402. Flip chip 404 includes substrate 408, which can comprise any suitable electrically insulating material, such as one of: silicon, sapphire, quartz, silicon dioxide, and silicon nitride.

Adjacent to substrate 408 is shield layer 410, which can be formed of a single, un-patterned superconducting metal layer as described above. Shield layer 410 may beneficially limit cross-talk between the noise-susceptible devices by at least reduction of magnetic interference. Each noise-susceptible device of noise-susceptible device wiring layer 416 may generate a magnetic field that decreases in strength proportionally with distance from the noise-susceptible device. As strength of magnetic field may decrease at a rate of n³ more quickly in the presence of a magnetic shield relative to an unshielded device, at least partial magnetic isolation may be achieved through separation of noise-susceptible device wiring layer 416 and shield layer 410 by a distance provided by separation space, gap, or layer 406. Undesired magnetic field interactions may be limited such that current flow in one noise-susceptible device might not induce current flow in a neighboring noise-susceptible device.

Though not shown, flip chip 404 can optionally include one or more layers arranged between substrate 408 and shield layer 410. These one or more layers may include devices that do not communicate with the noise-susceptible devices of noise-susceptible device wiring layer 416. As an example, one or more magnetometers may be arranged on flip chip 404.

Flip chip 404 and main chip 402 are arranged to be physically separated from one another by separation space, gap, or layer 406. Separation space, gap, or layer 406 can be implemented as a space or gap filled with air or another gas with similar, suitable dielectric properties and/or a vacuum or partial vacuum, which may behave as a dielectric layer that may perform better than a layer of a different dielectric material, such as those described with respect to portion 300. The dielectric constant of air is approximately the same the permittivity of a vacuum, which is considered a small or “low-K” dielectric value. Use of low-K materials may reduce parasitic capacitance and energy dissipation in the form of heat relative to dielectric materials having higher dielectric constants. This may better limit losses and noise seen by the plurality of noise-susceptible devices that occupy noise-susceptible device wiring layer 416. Separation space, gap, or layer 406 may replace a different dielectric layer within a fabrication stack, such as dielectric layers 328, 330, 332, and/or 334 of portion 300 of the multi-layer fabrication stack of FIG. 3. The use of a space, an air gap, and/or vacuum or partial vacuum avoids the inclusion of a noisy dielectric-metal interface that may interfere with the behavior of noise-susceptible devices and consequently reduce the accuracy of computations performed by a quantum processor formed in superconducting circuit 400.

A depth of space, gap, or layer 406 has a fixed distance that separates the external surface of flip chip 404 and noise-susceptible device wiring layer 416. The depth of space, gap, or layer 406 is uniform across a cross-section of a region of superconducting circuit 400 that includes noise-susceptible device wiring layer 416. In some implementations, the depth of space, gap, or layer 406 is uniform across the entire cross-section of superconducting circuit 400 or across an entire cross-section of a region including space, gap, or layer 406. In an alternative implementation, the depth of space, gap, or layer 406 might not be uniform across regions of the cross-section of superconducting circuit 400 that do not include noise-susceptible device wiring layer 416.

In some implementations, it is desirable for separation space, gap, or layer 406 to have a depth such that noise-susceptible device wiring layer 416 on main chip 402 and shield layer 410 on flip chip 404 are in as close of a proximity to one another as possible without touching. This prevents noise-susceptible device wiring layer 416 from electrically coupling to shield layer 410, which could create an interface that may introduce undesirable noise to the plurality of noise-susceptible devices.

Instead, separation space, gap, or layer 406 confines all or a portion of electric fields and magnetic fields between main chip 402 and flip chip 404. As no direct electrical connection exists between flip chip 404 and noise-susceptible device wiring layer 416, separation space, gap or layer 406 can hold charge noise present in electric fields in the air gap or vacuum while limiting transmission of this noise to the plurality of noise-susceptible devices. Similarly, separation space, gap, or layer 406 also confines some or all of flux noise present in magnetic fields, such that the confined noise might not be transmitted to the plurality of noise-susceptible devices. Confinement of electric and magnetic fields to separation space, gap, or layer 406 advantageously reduces or minimizes the effects of noise generated by two-state defects within insulating layers comprising dielectric materials or within dielectric-metal interfaces.

Mechanical coupler 412 is used to hold superconducting circuit 400 in place, such that the above-described effects can be realized. Mechanical coupler 412 can ensure that one or both of main chip 402 and flip chip 404 remain in a fixed arrangement that maintains separation space, gap, or layer 406. Mechanical coupler 412 can be implemented using any suitable structure (e.g., a frame, a clamp, etc.) that does not introduce undesired noise to superconducting circuit 400, and that is compatible with an environment in which superconducting circuit 400 is intended to be used. Preferably, mechanical coupler 412 does not introduce any additional material in close proximity to noise-susceptible device wiring layer 416.

Mechanical coupler 412 can optionally be a clamping mechanism or clamp. In some implementations, a jaw of a clamp can attach to one of substrate 414 of main chip 402 or substrate 408 of flip chip 404, such that the jaw can removably affix one of main chip 402 or flip chip 404 to a first additional surface. The chip that is not held by the clamp may be affixed to a second additional surface through a second clamp or clamping mechanism, or may be otherwise fixed in place. For instance, the chip may be held in a sample holder within a computing system that is at least partially located in a cryogenic environment.

In an alternative implementation, a first jaw of a clamp may be removably attached to substrate 414 of main chip 402 and a second jaw of the clamp may be removably attached to substrate 408 of flip chip 404.

Although examples of mechanical coupler 412 as one or more clamps or clamping mechanisms have been described, this is not intended to be limiting. Other mechanical spacers may be employed to maintain a fixed depth of separation space, gap, or layer 406 between main chip 402 and flip chip 404. As well, mechanical coupler 412 can be built into the system in which superconducting circuit 400 is to be used. For example, one of main chip 402 and flip chip 404 may be mounted onto a metallic cold plate in a cryogenic environment. The other one of main chip 402 and flip chip 404 may be affixed to a rigid strap formed of the same material as the metallic cold plate, which can hold the chip in place and provide separation space, gap, or layer 406.

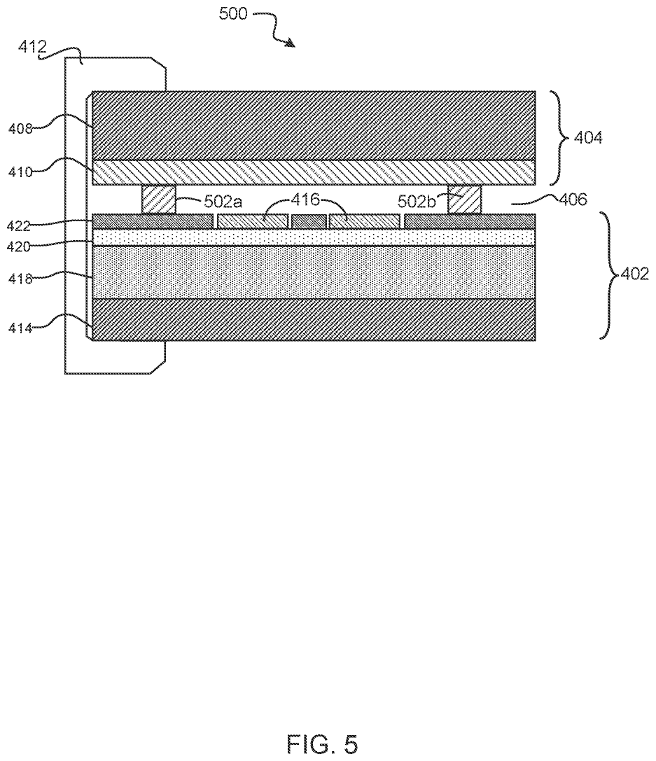

FIG. 5 is a cross-sectional view of a superconducting integrated circuit including a main chip, a shield flip-chip, and grounding bump bonds. A superconducting circuit 500 shown in FIG. 5 includes main chip 402 and flip chip 404 of FIG. 4, arranged to be spaced apart by separation space, gap, or layer 406. Superconducting circuit 500 includes all of the components of superconducting circuit 400. However, unlike superconducting circuit 400, superconducting circuit 500 also includes bump bonds 502a, 502b that electrically couples a ground of main chip 402 to flip chip 404. Bump bonds 502a, 502b are arranged such that they do not communicatively couple noise-susceptible device wiring layer 416 to flip chip 404. Bump bonds 502a, 502b conductively couple shield layer 410 to ground plane 422, which itself is not coupled to noise-susceptible device wiring layer 416 as described above. In some implementations, bump bonds 502a, 502b are comprised of indium.

Like superconducting circuit 400, superconducting circuit 500 can be all or at least a portion of quantum processor 126 of FIG. 1 and/or the quantum processor of FIGS. 2A and 2B. Each of elements 402 to 424 can be embodied as described above with respect to FIG. 4.

In FIG. 5, bump bonds 502a, 502b electrically couple shield layer 410 to ground plane 422 located on the external layer of main chip 402 that faces flip chip 404. The electrical connection of shield layer 410 to ground plane 422 forms a ground loop, that creates a path for undesired currents having electrical noise to exit shield layer 410. This may allow shield layer 410 to better limit cross-talk between the noise-susceptible devices on noise-susceptible device wiring layer 416. In some implementations, ground plane 422 can be electrically coupled to an external ground, such as a ground of a power terminal, to direct the undesired currents off superconducting circuit 400 entirely. In another implementation, ground plane 422 can be conductively coupled to one or more ground planes in multi-layer stack 418, for example, by one or more vias. At least one of the one or more ground planes in multi-layer stack 418 can direct the undesired currents off-chip through an electrical path to an external ground.

While bump bonds 502a, 502b provide electrical coupling of main chip 402 and flip chip 404, it is important that bump bonds 502a, 502b are not coupled to noise-susceptible device wiring layer 416. As such, no electrical connection is formed between the plurality of noise-susceptible devices and flip chip 404, such that the electrical and magnetic fields are confined to separation space, gap, or layer 406 as described above.

In an alternative implementation in which ground plane 422 is not included as part of main chip 402 of superconducting circuit 500, a superconducting circuit can optionally include one or more contact pads arranged on an external layer of a main chip facing a flip chip. The one or more contact pads would not be in communication with a plurality of noise-susceptible devices on a noise-susceptible device wiring layer, such that the contact pads would not be conductively, or otherwise galvanically, coupled to the portions of the plurality of noise-susceptible devices on the noise-susceptible device wiring layer. Instead, the contact pads may only be coupled only to other components and/or structures on underlying layers as described herein. One or more bump bonds can optionally be used to superconductingly electrically couple respective contact pads on the main chip to a shield layer that occupies an external surface of the flip chip. In some implementations, the one or more contact pads may comprise a superconducting metal, such as one of: niobium, aluminum, and tantalum.

The one or more contact pads may be further electrically coupled to a ground plane within a multi-layer stack, which may occupy a layer below the plurality of noise-susceptible devices on the main chip. This further electrical coupling may be achieved through vias arranged beneath the contact pads.

Although two bump bonds 502a, 502b are shown in FIG. 5, an implementation of the shield flip-chip arrangement is not limited in this manner. In some implementations, only one bump bond may be present. Alternatively, more than two bump bonds may be used to ground shield layer 410 of flip chip 404. However, it might not be preferable to include a large number of bump bonds in superconducting circuit 500 due in part to their space requirements. In implementations in which a footprint of superconducting circuit 500 is limited due to its intended installation location, bump bonds (e.g., 502a, 502b) may occupy space on main chip 402 that may otherwise be filled with additional noise-susceptible devices, thereby limiting the computational complexity of problems that can be solved using a quantum processor of superconducting circuit 500.

Though mechanical coupler 412 is shown in FIG. 5, it is not required. In some implementations, separation space, gap, or layer 406 of superconducting circuit 500 can optionally be maintained between noise-susceptible device wiring layer 416 and shield layer 410 using only bump bonds 502a, 502b between main chip 402 and flip chip 404.

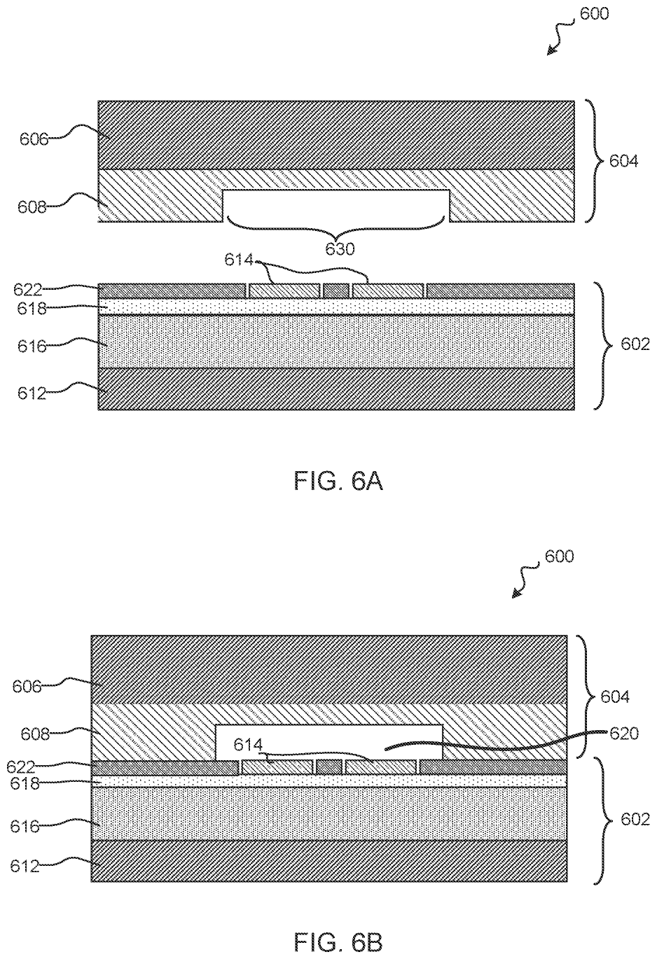

In another implementation, a main chip and a flip chip of the superconducting circuit according to the present disclosure can be arranged to lie flush against one another. This is illustrated in FIGS. 6A and 6B, which are cross-sectional views of a superconducting integrated circuit including a main chip and a shield flip-chip having a trench. A superconducting circuit 600 shown in FIGS. 6A and 6B can be all or at least a portion of quantum processor 126 of FIG. 1 and/or the quantum processor of FIGS. 2A and 2B. Superconducting circuit 600 includes a main chip 602 and a flip chip 604 having a trench 630, in which a depth of trench 630 provides a separation space, gap, or layer 620 between noise-susceptible devices on main chip 602 and flip chip 604.

FIG. 6A illustrates main chip 602 and flip chip 604 separately prior to mechanical coupling of the two chips in a flip-chip arrangement. FIG. 6B illustrates main chip 602 and flip chip 604 mechanically coupled in the flip-chip arrangement, such that separation space, gap, or layer 620 is formed between the two chips.

Flip chip 604 serves as a shield chip, and includes a shield layer 608 that directly overlies a substrate 606. Shield layer 608 occupies at least a portion of an external surface of flip chip 604 that faces main chip 602.

Main chip 602 includes all remaining components of superconducting circuit 600. Main chip 602 includes: a substrate 612 arranged as an external layer of main chip 602; a multi-layer stack 616 directly overlying substrate 612; a low-loss insulating layer 618 directly overlying multi-layer stack 616; and a noise-susceptible device wiring layer 614 directly overlying at least a portion of low-loss insulating layer 618. In some implementations, main chip 602 can optionally include a ground plane 622 on a same layer or level as, but not directly contacting, noise-susceptible device wiring layer 614. Ground plane 622 can also directly overlie a portion of low-loss insulating layer 618. In some implementations, ground plane 622 can comprise a superconducting metal.

Each of elements 612 to 618 and 622 of main chip 602 can be embodied as described above with respect to elements 414 to 422 of FIG. 4.

Flip chip 604 includes substrate 606, which can be comprised of any suitable electrically insulating material, such as one of: silicon, sapphire, quartz, silicon dioxide, and silicon nitride. Adjacent to substrate 606 is shield layer 608, which can be a single superconducting metal layer. Shield layer 608 may beneficially limit cross-talk between the noise-susceptible devices on main chip 602.

To confine all or some of the electrical and magnetic fields as described above with respect to superconducting circuit 400, a portion of the superconducting metal material forming shield layer 608 can be etched away. The etching may result in shield layer 608 having a “U” shape, in which absence of the etched material creates trench 630 aligned with the noise-susceptible devices on noise-susceptible device wiring layer 614 of main chip 602 along a cross-section of superconducting circuit 600. Alternatively, trench 630 can be formed using other fabrication techniques, such as through deposition of the superconducting material of shield layer 608 around a mask applied in a trench region.

As shown in FIG. 6B, flip chip 604 can be arranged to lie on top of main chip 602, such that trench 630 creates separation space, gap, or layer 620 that partially surrounds noise-susceptible device wiring layer 614, such that noise-susceptible device wiring layer 614 is encased by a combination of: side walls of trench 630, a surface of trench 630 that is substantially parallel to an external surface of noise-susceptible device layer 614, and a portion of main chip 602. Separation space, gap, or layer 620 provides the space, air gap, or vacuum or partial vacuum layer within superconducting circuit 600. A depth of space, gap, or layer 620 provides a fixed distance that separates noise-susceptible device wiring layer 614 and a substantially parallel surface of trench 630 on flip chip 604 thereto. The depth of space, gap, or layer 620 is uniform across its cross-section of superconducting circuit 600. The depth of space, gap, or layer 620 enables noise-susceptible device wiring layer 614 and the portion of shield layer 608 in trench 630 to be located in close proximity to one another without making physical contact. In some implementations, the depth of trench 630 (i.e., the depth separation space, gap, or layer 620) may be on a scale of hundreds of nanometers.

Separation space, gap, or layer 620 can prevents electrical coupling of noise-susceptible device wiring layer 614 and flip chip 604, and instead confine some or all of charge noise that would otherwise be transmitted to the plurality of noise-susceptible devices via a noisy interface. Separation space, gap, or layer 620 formed by trench 630 can similarly trap flux noise.

In some implementations, trench 630 can have a footprint slightly larger than a footprint of noise-susceptible device wiring layer 614 or portion thereof. When main chip 602 and flip chip 604 are mechanically coupled in their flip-chip configuration, this enables separation space, gap, or layer 620 to surround the portions of the plurality of noise-susceptible devices that, without flip chip 604, would otherwise be exposed to the environment.

Hereinafter, one or more structures that can “partially surround” or be “partially surrounding” at least portions of the plurality of noise-susceptible devices or the noise-susceptible device layer can refer to one or more structures that indirectly or directly covers the at least portions of the plurality of noise-susceptible devices or the noise-susceptible device layer, such that the one or more structures extend along at least two surfaces thereof. As well, “encasing” at least portions of the plurality of noise-susceptible devices or the noise-susceptible device layer can refer to surrounding the at least portions of the plurality of noise-susceptible devices or the noise-susceptible device layer on all sides.

Although FIGS. 6A and 6B show trench 630 in the center of flip chip 604, trench 630 may be formed at any location along the cross-section of superconducting circuit 600. The location of trench 630 is dependent only on a location of noise-susceptible device wiring layer 614, which similarly is not required to be centered on the external surface of main chip 602 facing flip chip 604.

FIGS. 6A and 6B show a single trench arranged at a single location along the cross-section of flip chip 604, and the plurality of noise-susceptible devices arranged at a single location along the cross-section of main chip 602. However, this is not intended to be limiting. There can optionally be noise-susceptible devices arranged at a plurality of locations along the cross-section of main chip 602. Subsequently, there can optionally be a respective plurality of trenches aligned with the locations of the noise-susceptible devices along the cross-section of superconducting circuit 600.

Main chip 602 and flip chip 604 can be fixed in place relative to one another in a variety of different manners. Regardless of the technique employed, a portion of shield layer 608 and a portion of grounding plane 622 can be arranged to lie flush against one another. As such, the external surfaces of shield layer 608 and grounding plane 622 may be fabricated using methods that ensure high-quality planarization.

In some implementations, a mechanical coupler can be employed, such as mechanical coupler 412 described above with respect to FIG. 4. In some implementations, bump bonds can be employed to provide mechanical coupling of main chip 602 and flip chip 604, as well as galvanic coupling between flip chip 604 and a portion of main chip 602 that excludes noise-susceptible device wiring layer 614. For example, bump bonds 502a, 502b described above with respect to FIG. 5 may be included in superconducting circuit 600 when ground plane 622 is present. If optional ground plane 622 is absent from superconducting circuit 600, bump bonds may be superconductingly electrically connected to contact pads that are arranged on main chip 602, but which are not communicatively coupled to noise-susceptible device wiring layer 614 (i.e., contact pads on main chip 602 are not electrically conductively, or otherwise galvanically, coupled to the portions of noise-susceptible devices on noise-susceptible device wiring layer 614).

In addition to the techniques described above, at least a portion of shield layer 608 and a portion of grounding plane 622 can be fixed to one another using an adhesive and/or other material that does introduce additional noise to superconducting circuit 600.

In some implementations, ground plane 622 can optionally be absent from superconducting circuit 600, and shield layer 608 may be in contact with low-loss insulating layer 618. Any of the above affixation techniques may still be employed, providing that an additional noisy interface is not established and/or the amount of noise introduced by affixation is below a threshold amount.

Superconducting circuits 400, 500, and 600 of FIGS. 4, 5, 6A, and 6B integrate high-coherence noise-susceptible devices of scalable quantum processors with structures to control and shield the noise-susceptible devices within the quantum processor.

Shield layers 410, 608 on flip chips 404, 604 beneficially reduce cross-talk between the plurality of noise-susceptible devices on noise-susceptible device wiring layers 416, 614 of main chips 402, 602.

Noise-susceptible device wiring layers 416, 614 are arranged on external layers of main chips 402, 602 that face flip chips 404, 604 to eliminate adjacent noisy dielectric-metal interfaces. Separation spaces, gaps, or layers 406, 620 of superconducting circuits 400, 500, 600 instead confine electrical and magnetic fields therein. This arrangement may advantageously reduce an amount of flux and charge noise transmitted to noise-susceptible devices, resulting in a reduction of loss of quantum information. Limitation of loss and the effects of noise may improve coherence of noise-susceptible devices like qubits.

The arrangements of superconducting circuits 400, 500, and 600 may realize the benefits of multi-layer fabrication stacks, such as those described above with respect to FIG. 3, and of high-coherence structures for increasing computation time available for quantum processors that include a plurality of qubits.

### Control Flip-Chip for High-Coherence Superconducting Integrated Circuit

In addition to the use of a shield flip chip as described above, a superconducting circuit having a flip-chip configuration can also be used to separate a plurality of qubits and couplers from other structures and materials included in a multi-layer fabrication stack. This approach may more closely resemble the high-coherence qubit fabrications known in the art, in which a qubit chip may include only two layers: a substrate having a low loss tangent and a single metal layer including qubit wiring overlying the substrate. By providing a multi-layer stack on a flip chip that communicates with the qubit chip without galvanically coupling to the qubits, the superconducting circuit can also realize the advantages of a multi-layer fabrication stack, such as: an increased number of qubits/couplers and qubit/coupler density, reduced cross-talk, and increased on-chip capabilities due to the presence of other devices.

As used herein, galvanic coupling refers to electrical coupling achieved through one or more elements (e.g., a wire) that is physically shared between the coupled circuits. Galvanic coupling may also be referred to herein as a direct conductive connection. A direct conductive connection is formed between the circuits through the shared element, providing a direct electrical connection to couple the circuits. In contrast, inductive coupling refers to coupling achieved through interaction of one or more magnetic fields between the circuits without a direct electrical connection. A current transmitted through a portion of a first circuit creates a magnetic field around the first circuit, inducing a current in the second circuit.

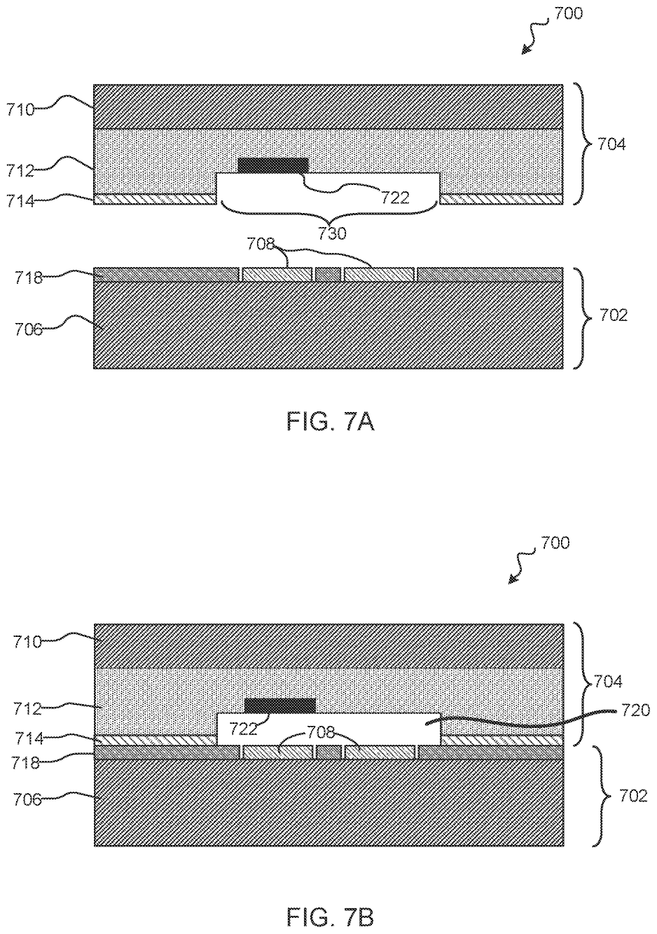

FIGS. 7A and 7B are cross-sectional views of a superconducting integrated circuit including a qubit chip and a control flip-chip having a trench. A superconducting circuit 700 shown in FIGS. 7A and 7B can be all or at least a portion of quantum processor 126 of FIG. 1 and/or the quantum processor of FIGS. 2A and 2B. Superconducting circuit 700 includes a qubit chip 702 and a control flip chip 704 having a trench 730, such that trench 730 creates a space or a layer that provides a vacuum, or a partial vacuum, or a space, gap, or layer that is filled with air (herein referred to as: “separation space, gap, or layer 720”), that spaces apart flip chip 704 from the noise-susceptible devices on qubit chip 702.

FIG. 7A illustrates qubit chip 702 and control flip chip 704 separately prior to mechanical coupling of the two chips in a flip-chip arrangement. FIG. 7B illustrates qubit chip 702 and control flip chip 704 mechanically coupled in the flip-chip arrangement, such that portions of an external surface of qubit chip 702 and flip chip 704 lie flush against one another and trench 730 provides separation space, gap, or layer 720 as a space, an air gap or vacuum, and/or partial vacuum between the two chips.

Qubit chip 702 can include a plurality of noise-susceptible devices, such as a plurality of qubits and couplers. In some implementations, these devices may each have decoherence times on the order of 1 μs. In superconducting circuit 700, qubit chip 702 is a chip including a substrate 706 and a noise-susceptible device layer 708 overlying at least a portion of substrate 706. Optionally, a qubit shield layer 718 can occupy a same layer as noise-susceptible device layer 708, and also overlying a portion of substrate 706. In some implementations, qubit shield layer 718 can comprise a metal that exhibits superconducting behavior at and below a critical temperature. In some implementations, qubit shield layer 718 is not patterned and does not include electrical traces.

Substrate 706 can comprise a suitable dielectric material with a sufficiently low loss tangent. In some implementations, the suitable dielectric material may have a loss tangent less than 10⁻⁶. In some implementations, substrate 706 may comprise high resistivity, single-crystal silicon, such as silicon nitride. In other implementations, substrate 706 may comprise sapphire.

The plurality of noise-susceptible devices can be formed within noise-susceptible device layer 708. In some implementations, the noise-susceptible devices may include programmable devices (qubits and coupling devices) 230 of portion 200b of a quantum processor, which can include, for example, qubits 201, 202 and coupler 210 of circuit 200a. Qubits and couplers of noise-susceptible device layer 708 can comprise a low-noise superconducting material. The low-noise superconducting material can be a material that exhibits superconducting behavior at and below a critical temperature, and can optionally be aluminum. The superconducting loops and other wiring of the plurality of noise-susceptible devices may comprise aluminum.

Respective Josephson junctions of each of the qubits and couplers, such as Josephson junctions 231, 232, 229 of qubits 201, 202 and coupler 210, can optionally be fabricated as part of noise-susceptible device layer 708 using double-angle evaporation fabrication techniques. Like the other portions of the noise-susceptible devices, the metal layer(s) of each Josephson junction structure can comprise aluminum. In some implementations, other suitable low-noise fabrication techniques may be used to form the Josephson junctions within noise-susceptible device layer 708.

Control flip chip 704 can provide at least some of the remaining circuitry of the multi-layer fabrication stacks described above. In some implementations, control flip chip 704 may include, for example, at least a portion of the multi-layer fabrication stack shown in FIG. 3. In FIGS. 7A and 7B, control flip chip 704 of superconducting circuit 700 includes: a substrate 710; a multi-layer control stack 712 directly overlying substrate 710; and, a shield layer 714 overlying a portion of multi-layer control stack 712.

In some implementations, control flip chip 704 can include some or all of layers 304 to 336 of portion 300 of the multi-layer fabrication stack of FIG. 3, as described above. Control flip chip 704 may also include additional layers that are not shown in portion 300, such as additional superconducting metal layers and shield layers. Multi-layer control stack 712 may include without limitation, for example, some or all of the following: multiple metal layers (e.g., wiring layers) and interlayer dielectrics, vias (vertical interconnect accesses), Josephson junctions, and flux storage devices. Control flip chip 704 may also include, for example, devices that form programming subsystem 233, readout circuit(s) 240, coupler control circuit(s) 238, and qubit control circuit(s) 236 of the quantum processor of FIG. 2B.

Substrate 710 of control flip chip can comprise any suitable electrically insulating material, such as one of: silicon, sapphire, quartz, silicon dioxide, and silicon nitride. Substrate 302 of portion 300 may be implemented as substrate 710 of superconducting circuit 700.

Multi-layer control stack 712 can include any or all of the above-noted remaining layers of control flip chip 704. Particularly, multi-layer control stack 712 includes circuitry to control the plurality of noise-susceptible devices of noise-susceptible device layer 708 of qubit chip 702. The plurality of noise-susceptible devices may be controlled via signals applied to influence their operation. For instance, a biasing signal may be applied to the superconducting loops of qubits 201, 202 of circuit 200a to modify their respective fluxes during programming and/or computation of the quantum processor. As this may be performed via programming interfaces 222, 223 included in qubit control circuit(s) 236 of portion 200b, these components of the quantum processor of FIG. 2 may be included as part of multi-layer control stack 712 of superconducting circuit 700.

The circuitry to control the plurality of noise-susceptible devices includes one or more programmable devices, such as superconducting DACs that convert and/or store signals prior to applying these signals to the noise-susceptible devices. The superconducting DACs of multi-layer control stack 712 can comprise one or more materials that exhibit superconducting behavior at and below a respective critical temperature, such as: niobium, aluminum, and tantalum. Each superconducting DAC can include the following components: a Josephson junction, a superconducting loop, a communicative interface, and an energy storage component. Each superconducting DAC may store energy in a respective magnetic field resulting from a flux rate-of-change of the energy storage inductor to generate a magnetic inductance. The resultant magnetic inductance may be used to transmit a control signal to noise-susceptible devices via a communicative interface.

In some implementations, the energy storage component can optionally be a magnetic coil comprised of a material that exhibits superconducting behavior at and below a critical temperature.

In some implementations, the energy storage component of the one or more DACs can optionally comprise a high kinetic inductance material that is coupled to a respective superconducting loop that does not comprise a high kinetic inductance material. In other implementations, one or more entire DACs can optionally be formed within a single layer of multi-layer control stack 712 from a high kinetic inductance material.

The high kinetic inductance material that comprises at least the energy storage component of some of the above-described DACs may be at least one of one: WSi, MON, NbN, NbTIN, TIN, and granular aluminum. Further detail on DAC-based control circuits formed of high kinetic inductance materials is described in International Patent Application Publication No. 2022/178130.

The operation of Josephson junctions and/or compound Josephson junctions in DACs is described in greater detail in U.S. Pat. Nos. 7,876,248; 8,098,179; and, 11,127,893, and U.S. Patent Application Publication No. 2018/0101786.

In some implementations, control circuitry in multi-layer control stack 712 can optionally include at least one superconducting DAC having multiple interconnected stages, increasing a range or granularity of control over the behavior of the plurality of noise-susceptible devices in noise-susceptible device layer 708.

The superconducting DACs and other components of the control circuitry may be formed across a plurality of layers in multi-layer control stack 712. Components of and/or connections between superconducting DACs and/or other components of the control circuitry may traverse layers of multi-layer control stack 712 to provide inductive or galvanic communicative coupling. For example, superconducting vias may be used to electrically couple components of the control circuitry that are located on different layers.

In order to communicate with noise-susceptible devices on noise-susceptible device layer 708, a communicative interface 722 of the control circuit may be arranged on an external surface of control flip chip 704 that faces qubit chip 702. In FIGS. 7A and 7B, communicative interface 722 is shown within multi-layer control stack 712. In some implementations, communicative interface 722 can be at least one control coupler interrupting a respective superconducting loop of a superconducting DAC. Each control coupler can inductively transmit a control signal to one or more corresponding noise-susceptible devices.

In addition to circuitry for controlling noise-susceptible devices in noise-susceptible device layer 708 of qubit chip 702, multi-layer control stack 712 can optionally include other devices. This may include DACs used for storage, programming, and readout within superconducting circuit 700. Examples of applications of DACs for these and other purposes are described in greater detail in U.S. Pat. Nos. 7,876,248 and 8,098,179.

Shield layer 714 can be arranged to overlie all the wiring of multi-layer control stack 712, except communicative interface 722 of the control circuit (e.g., a communicative interface of the superconducting DAC described above). Shield layer 714 can be comprised of a superconducting metal, such as: niobium, aluminum or tantalum, and may reduce cross-talk between noise-susceptible devices of noise-susceptible device layer 708. Shield layer 714 and shield planes within multi-layer control stack 712 can direct magnetic fields generated within multi-layer control stack 712 away from noise-susceptible device layer 708. Shield layer 714 is not patterned to include any electrical traces, and may not carry any desired electrical signals used in the operation of a quantum processor. In some implementations, shield layer 714 might not be in conductive communication with any other components of superconducting circuit 700.

Trench 730 is formed in the external surface of control flip chip 704 that faces qubit chip 702. Trench 730 is aligned with the noise-susceptible devices of noise-susceptible device layer 708 on qubit chip 702, and resulting separation space, gap, or layer 720 surrounds the portion of the noise-susceptible devices that were previously exposed to the environment (i.e., the noise-susceptible devices is partially surrounded by separation space, gap, or layer 720, as noise-susceptible device layer 708 is encased by a combination of: side walls of trench 730, a surface of trench 730 that is substantially parallel to the external surface of noise-susceptible device layer 708, and a portion of substrate 706). In some implementations, trench 730 can be formed by etching away a portion of the material of shield layer 714. In some implementations, a portion of the material of multi-layer control stack 712 may also be etched away to form trench 730. Following etching, communicative interface 722 of the control circuit is exposed on the etched surface of trench 730. Alternatively, trench 730 may be formed by deposition of material(s) of shield layer 608 and/or layers of multi-layer control stack 712 around a mask applied over a trench region that includes communicative interface 722.

Separation space, gap, or layer 720 provides a space, an air gap, and/or vacuum or partial vacuum layer within superconducting circuit 700. Like superconducting circuits 400, 500, and 600, this space, air gap, vacuum, or partial vacuum layer precludes direct electrical coupling (i.e., direct conductive coupling and/or galvanic coupling) between the noise-susceptible devices and flip chip 704. The space, air gap, and/or vacuum or partial vacuum layer confines therewithin all or a portion of the electrical and magnetic fields generated by multi-layer control stack 712. This advantageously limits amounts of flux noise and charge noise transmitted to the noise-susceptible devices that would reduce device decoherence time. The space, air gap, and/or vacuum or partial vacuum layer eliminates the need for a dielectric insulating layer between noise-susceptible device layer 708 and the layers of control flip chip 704, thereby eliminating a potentially lossy and noisy dielectric-metal interface.

A depth of space, gap, or layer 720 provides a fixed distance that separates communicative interface 722 on control flip chip 704 and noise-susceptible device layer 708 on qubit chip 702. The depth of space, gap, or layer 720 is uniform across its cross-section of superconducting circuit 700. Trench 730 (and thus separation space, gap, or layer 720) can have a depth allowing noise-susceptible device layer 708 and communicative interface 722 to be in close enough proximity to one another to enable non-galvanically coupling such that a control signal transmitted thereacross degrades by an acceptably low amount. In some implementations, the depth of trench 730 may be on the scale of hundreds of nanometers.

The magnetic fields generated by the control circuitry of control flip chip 704 have low frequencies such that shield mechanisms, including shield layer 714, can disallow modes at their drive frequencies to maintain only the DC components of the generated fields. This may beneficially prevent non-local coupling, noise arising from radiation, and population of modes.

Although FIGS. 7A and 7B show trench 730 in the center of control flip chip 704, trench 730 may be formed at any location on the cross-section of superconducting circuit 700. The location of trench 730 is dependent only on a location of noise-susceptible device layer 708, which similarly is not required to be centered on the external surface of qubit chip 702 facing control flip chip 704.

FIGS. 7A and 7B show a single trench arranged at a single location along the cross-section of control flip chip 704, and the plurality of noise-susceptible devices arranged at a single location along the cross-section of qubit chip 702. However, this is not intended to be limiting. There can optionally be noise-susceptible devices arranged at a plurality of locations along the cross-section of qubit chip 702. Subsequently, there can optionally be a respective plurality of trenches aligned with the locations of the noise-susceptible devices along the cross-section of superconducting circuit 700, each having a communicative interface 722 exposed on an etched surface of control flip chip 704 (i.e., on a surface of trench 730 that is substantially parallel to an external surface of qubit chip 702).

Qubit chip 702 and control flip chip 704 can be held in the flip-chip configuration of FIG. 7B in a variety of different manners. In some implementations, a mechanical coupler can be employed, such as mechanical coupler 412 described above with respect to FIG. 4.

In some implementations, at least a portion of shield layer 714 and a portion of qubit shield layer 718 can be fixed to one another using an adhesive and/or other material that does not introduce significant additional noise to superconducting circuit 700.

In implementations in which qubit shield layer 718 is absent from superconducting circuit 700, shield layer 714 can optionally be in physical contact with substrate 706 of qubit chip 702. Any of the described affixation techniques may still be employed, providing that no additional noisy interface is established.

In an alternative implementation, a superconducting circuit can be designed such that a separation space, gap, and/or vacuum or partial vacuum layer is formed between a protrusion of a control flip chip and a trench of a qubit chip. A noise-susceptible device layer can be located on an external surface of the trench of the qubit chip. A communicative interface can be arranged on an external surface of the protrusion of the control flip chip. The opposing external surfaces of the control flip chip and the qubit chip can be arranged to physically couple to one another at locations that exclude the protrusion of the control flip chip and the trench of the qubit flip chip.

A depth of the trench of the qubit flip chip can exceed a depth of the protrusion of the control flip chip to prevent physical and galvanic contact between the noise-susceptible devices formed on the noise-susceptible device layer and the control circuitry of a multi-layer control stack. A difference between the depth of the trench and the depth of the protrusion may provide a depth of the separation space, gap, and/or vacuum or partial vacuum layer that allows for the communicative interface to transmit signals to the noise-susceptible devices.

In some implementations, the protrusion on the control flip chip may be formed by etching its external surface outside of a desired protrusion region that includes the communicative interface. An etching depth may determine a depth of the protrusion. Alternatively, a mask may be applied to areas outside of the desired protrusion region. The protrusion may be formed through deposition of one or more layers of the multi-layer control stack, which may be patterned to include control circuitry and/or devices. The material of the multi-layer control stack builds up the area of the protrusion to a desired depth, and the communicative interface is formed on an external surface of the protrusion.

In some implementations, material can be etched from a substrate of the qubit chip in a desired trench region to form the trench, and then the noise-susceptible device layer can be formed on the external surface of the etched location in some implementations. Alternatively, the trench may be formed by: deposition of material of the substrate; deposition of a layer of low-loss superconductive metal, patterning the layer of low-loss superconductive metal, and formation of Josephson junctions to form the noise-susceptible devices of the noise-susceptible device layer; application of a mask to the noise-susceptible device layer; and, deposition of an amount of the material of the substrate that corresponds with the desired trench depth.

The implementation in which a separation space, gap, and/or vacuum or partial vacuum layer is formed between a protrusion in a control flip chip and a trench in the qubit chip may reduce an amount of vertical space occupied by a superconducting circuit, such as one similar to superconducting circuit 700. This may be advantageous in arrangements in which multi-layer control stack 712 includes several layers having several devices, which may result in a tall control flip chip 704. This arrangement allows chips to be easily stacked and fit together in a space-conscience manner, which may be extended to the stacking of a plurality of chips that are to be placed at a same location of a hybrid computing system, such as hybrid computing system 100 of FIG. 1.

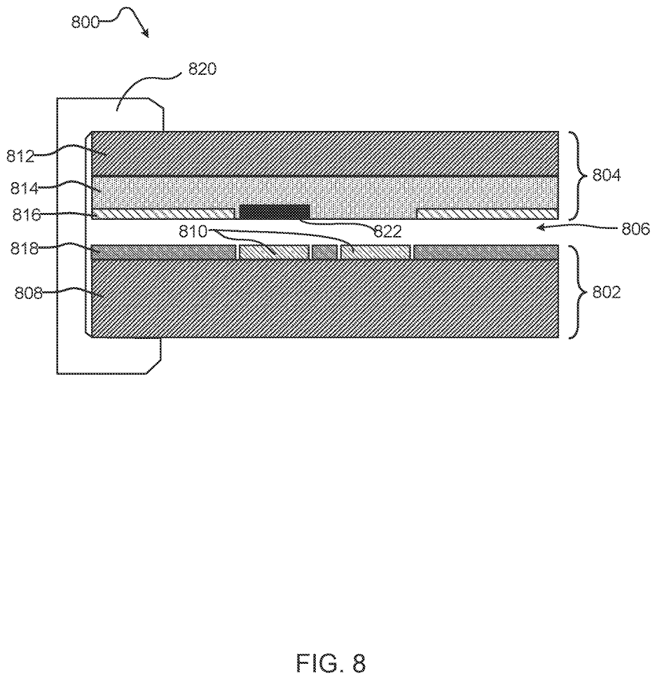

FIG. 8 is a cross-sectional view of another example implementation of the superconducting integrated circuit including a qubit chip and a control flip chip. A superconducting circuit 800 shown in FIG. 8 can be all or at least a portion of quantum processor 126 of FIG. 1 and/or the quantum processor of FIGS. 2A and 2B. Superconducting circuit 800 includes a qubit chip 802 and a control flip chip 804 which are fixed in place by mechanical coupler 820 at a distance to form a separation space, gap, or layer 806.

Qubit chip 802 includes a substrate 808 and a noise-susceptible device layer 810 directly overlying a portion of substrate 808. Optionally, qubit chip 802 can also include a qubit shield layer 818 on a same layer as noise-susceptible device layer 810 that also directly overlies a portion of substrate 808. Each of elements 808, 810, and 818 of qubit chip 802 can be embodied as described above with respect to elements 706, 708, and 716, respectively, of qubit chip 702 of FIGS. 7A and 7B.

Control flip chip 804 includes: a substrate 812; a multi-layer control stack 814 directly overlying substrate 812; and, a shield layer 816 that directly overlies a first portion of multi-layer control stack 814 and occupies a same layer as a second portion of multi-layer control stack 814. Each of elements 812, 814, and 816 can be embodied as described above with respect to elements 710, 712, and 714, respectively, of control flip chip 704 of FIGS. 7A and 7B.

As can be seen in FIG. 8, superconducting circuit 800 does not include a trench in control flip chip 804. Instead, a communicative interface 822 of the control circuit occupies the second portion of multi-layer control stack 814, which is an external surface of control flip chip 804 facing qubit chip 802 and does not underlie shield layer 816.

Separation space, gap, or layer 806 behaves similarly to separation space, gap, or layer 720 of superconducting circuit 700, which mitigates noise and allows control flip chip 804 to transmit control signals to qubit chip 802.

A depth of space, gap, or layer 806 provides a fixed distance (i.e., does not change over time once the qubit chip 802 and control flip chip 804 are arranged in the flip-chip configuration) that separates communicative interface 822 and noise-susceptible device layer 810. The depth of space, gap, or layer 806 is uniform across a cross-section of superconducting circuit 800 that includes noise-susceptible device wiring layer 416 and communicative interface 822. In some implementations, the depth of space, gap, or layer 806 is uniform across the entire cross-section of superconducting circuit 800 or across an entire cross-section of space, gap, or layer 806. In an alternative implementation, the depth of space, gap, or layer 806 might not be uniform across regions of the cross-section of superconducting circuit 800 that do not include communicative interface 822 and noise-susceptible device layer 810.

Separation space, gap, or layer 806 can have a depth that places qubit chip 802 and control flip chip 804 in close enough proximity to one another such that communicative interface 822 can communicatively couple to one or more devices of the plurality of noise-susceptible devices without physical and/or galvanic contact therebetween. In some implementations, the depth of separation space, gap, or layer 806 may be on a scale of hundreds of nanometers.

Mechanical coupler 820 can be affixed to one or both of qubit chip 802 and control flip chip 804 to maintain the fixed distance of separation space, gap, or layer 806. Mechanical coupler 820 can be implemented using any suitable means that does not introduce undesired noise and that is compatible with an environment in which superconducting circuit 800 is intended to be used. Mechanical coupler 820 can be embodied using any of the techniques described above with reference to mechanical coupler 412 of FIG. 4.

Though not shown in FIG. 8, superconducting circuit 800 can optionally include galvanic coupling between control flip chip 804 and a portion of qubit chip 802 that is not galvanically coupled to the noise susceptible devices. This may be achieved using one or more grounding bump bonds, which may be arranged similarly to bump bonds 502a, 502b of superconducting circuit 500 in FIG. 5.

Superconducting circuits 700, 800 of FIGS. 7 and 8 may advantageously provide at least a portion of a quantum processor including high-coherence qubits and a separated multi-layer stack such that the processor is scalable and can be flexibly controlled.

Qubit chips 702, 802 include only noise-susceptible devices on a layer overlying a low-loss, low-noise substrate, which limits exposure of the noise-susceptible devices to several common noise sources arising from a multi-stack circuit in a quantum processor. Examples of such limited noise sources may include: noise generated at a dielectric-metal interface, noise generated during operation of a control circuit, environmental noise introduced to the control circuit by an external signal path, and black-body radiation.

However, superconducting circuits 700, 800 non-galvanically, communicatively couple the noise-susceptible devices on qubit chips 702, 802 with communicative interfaces 722, 822 of control flip chips 704, 804 to receive control signals generated by one or more control circuits in multi-layer control stacks 712, 814. This may beneficially electrically isolates the noise-susceptible devices for an improved qubit decoherence time, while also providing the advantages of integrating a multi-layer control stack in a quantum processor.

### Other Non-Electrical Coupling Arrangements for High-Coherence Superconducting Integrated Circuits

In some implementations, a superconducting circuit having several of the characteristics of superconducting circuits 700 and 800 might not include two separate chips arranged in a flip-chip configuration. Instead, an alternative superconducting circuit can include a first circuit with high-coherence qubits and a second circuit with a multi-layer control circuit that are formed on opposing sides of a single silicon wafer. Unlike in solutions known in the art, this alternative superconducting circuit does not include bump bonds or vias that traverse the single silicon wafer, such that the second circuit can transmit control signals to the qubits of the first circuit through the single silicon wafer without conductive and/or galvanic coupling or physical contact therebetween.

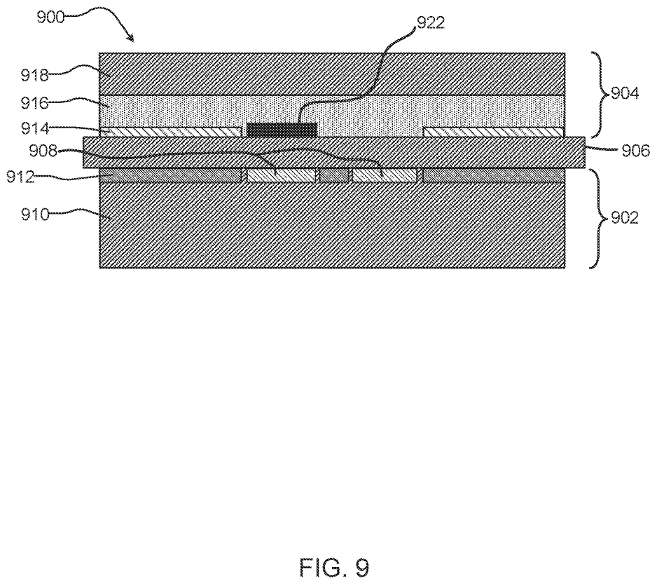

FIG. 9 is a cross-sectional view of an example implementation of a superconducting integrated circuit including a high-coherence qubit circuit and a multi-layer control circuit formed on opposing sides of a single chip. A superconducting circuit 900 shown in FIG. 9 can be all or at least a portion of quantum processor 126 of FIG. 1 and/or the quantum processor of FIGS. 2A and 2B. Superconducting circuit 900 includes a spacing substrate 906. A qubit circuit 902 is formed on a first external surface of spacing substrate 906, and a multi-layer control circuit 904 is formed on an opposing external surface of spacing substrate 906 relative to qubit circuit 902.

In the description of superconducting circuit 900 below, the terms “overlie” and “underlie” describe a position of a layer and/or component in relation to spacing substrate 906, since both qubit circuit 902 and multi-layer control circuit 904 are formed using spacing substrate 906 as a base. While such assumes a particular orientation of spacing substrate 906 for ease of discussion, such is not intended to be limiting. Thus, the orientation as illustrated in FIG. 9 can be flipped upside down, for example.

Qubit circuit 902 of FIG. 9 includes: a noise-susceptible device layer 908 directly underlying at least a portion of spacing substrate 906; a qubit circuit substrate 910 directly underlying noise-susceptible device layer 908; and, optionally, a qubit shield layer 912 arranged to overlie at least a portion of qubit circuit substrate 910 and underlie at least a portion of spacing substrate 906. Qubit circuit 902 and its elements (908, 910, 912) can be implemented in the same manner as qubit chips 702 and 802 of superconducting circuits 700 and 800.

Multi-layer control circuit 904 of FIG. 9 includes: a shield layer 914 directly overlying a portion of spacing substrate 906; a multi-layer control stack 916 having a first portion directly overlying shield layer 914 and a second portion directly overlying spacing substrate 906; and, a control circuit substrate 918 directly overlying multi-layer control stack 916. Shield layer 914 overlies all control wiring of multi-layer control stack 916 excluding a communicative interface 922 used to transmit signals to the plurality of noise-susceptible devices of noise-susceptible device layer 908 on qubit circuit 902. Multi-layer control circuit 904 and its elements (914, 916, 918, 922) can be implemented in the same manner as control flip chips 704 and 804 of superconducting circuits 700 and 800.

Spacing substrate 906 can be a wafer comprising a low-noise insulating material. In some implementations, spacing substrate 906 can optionally comprise a high-resistivity, single-crystal silicon. In other implementations, spacing substrate 906 can optionally comprise sapphire. Spacing substrate 906 can ensure that noise-susceptible device layer 908 does not electrically couple to multi-layer control stack 916 or other components of multi-layer control circuit 904.

The material of spacing substrate 906 may beneficially trap a significant portion of flux noise and charge noise of fields generated by multi-layer control stack 916, which prevents transmission of this noise to noise-susceptible device layer 908. Spacing substrate 906 can have a depth that allows communicative interface 922 of multi-layer control stack 916 to communicate with noise-susceptible devices on noise-susceptible device layer 908 without degradation of the transmitted signals.

In FIG. 9, qubit circuit 902 is shown to underlie spacing substrate 906, and multi-layer control circuit 904 is shown to overlie spacing substrate 906 of superconducting circuit 900. However, in an alternative implementation, qubit circuit 902 can instead overlie spacing substrate 906 and multi-layer control circuit 904 can underlie spacing substrate 906.

To fabricate superconducting circuit 900, spacing substrate 906 may first be provided. Then, one of qubit circuit 902 and multi-layer control circuit 904 is formed on a first external surface of spacing substrate 906 and the other one of qubit circuit 902 and multi-layer control circuit 904 is formed on a second external surface of spacing substrate 906 that opposes the first external surface.

Superconducting circuit 900 may realize several of the benefits of superconducting circuits 700, 800, and provides a superconducting circuit that may include at least a portion of a quantum processor having several high-coherence qubits for solving complex problems with integration of structures to shield, address, and control the qubits.

Separation of the noise-susceptible devices and multi-layer control circuit 904 across spacing substrate 906 may limit noise and loss realized by interfaces in the fabrication stacks known in the art. The absence of conductive and/or galvanic coupling between noise-susceptible device layer 908 and multi-layer control circuit 904 may lessen an amount of noise transmitted to the qubits that may reduce processor precision and qubit decoherence times.

Formation of qubit circuit 902 may include low-noise fabrication techniques, which may be more difficult and expensive to perform than more conventional fabrication techniques that may be suitable to form multi-layer control circuit 904. By separating the fabrication processes of qubit circuit 902 and multi-layer control circuit 904, even though both are formed on spacing substrate 906, the fabrication process of a low-noise, high-coherence superconducting circuit may be simpler and less resource-intensive than a single-stack fabrication of superconducting circuits having similar properties.

In some implementations of superconducting circuits 400, 500, 600, one or both of main chip 402, 602 and flip chip 404, 604 can optionally be formed in a manner similar to superconducting circuit 900. For example, a substrate of low-loss material may first be thinned down like spacing substrate 906, but may be used as low-loss insulating layer 420, 618 of main chip 402, 602. Noise-susceptible device wiring layer 416, 614 and optionally ground plane 422, 622 may be formed to overlie low-loss insulating layer 420, 618. Multi-layer stack 418, 616 and substrate 414, 612 may be formed to underlie low-loss insulating layer 420.

Likewise, in some implementations of superconducting circuits 700, 800, one or both of qubit chip 702, 802 and control flip chip 704, 804 can optionally be formed in a manner similar to superconducting circuit 900.

### Methods

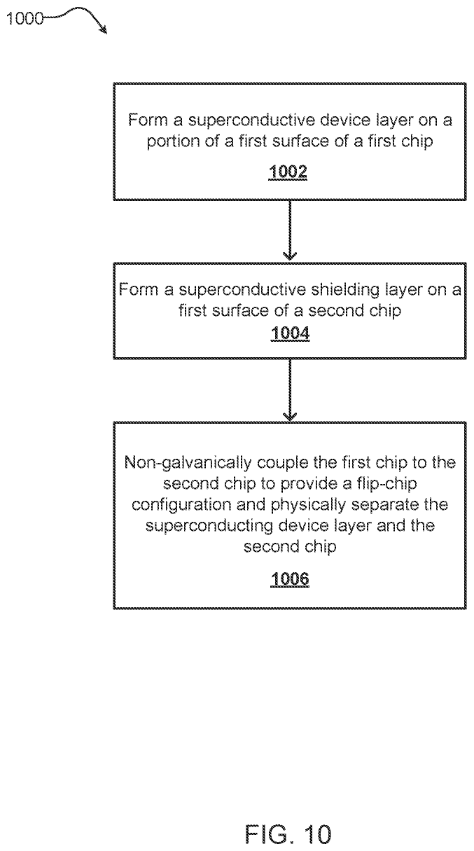

FIG. 10 is a flowchart illustrating a method 1000 to fabricate a superconducting integrated circuit having a flip-chip configuration for high coherence, in accordance with the present articles and methods. Method 1000 provides an example method to fabricate any one of superconducting circuits 400, 500, 600, 700, and 800 described above.

Method 1000 includes acts 1002 to 1006, though in other implementations, certain acts may be omitted and/or additional acts may be added. Method 1000 may be performed by, for example, integrated circuit fabrication equipment in response to an initiation of a fabrication process.

At 1002, a superconducting device layer is formed on a portion of a first surface of a first chip. In some implementations, the superconducting device layer can include programmable devices (qubits and coupling devices) 230 of portion 200b, including one or more qubits and optionally one or more couplers to communicatively couple qubits, such as qubits 201, 202 and coupler 210 of circuit 200a.

Formation of the superconducting device layer may, for example, include depositing, planarizing and/or etching a low-noise superconducting material on an external layer of the first chip. The low-noise superconducting material can optionally comprise aluminum. In some implementations, in which the superconducting device layer includes one or more qubits, qubits can optionally be formed using aluminum double-angle evaporation techniques known in the art. Alternatively, other suitable low-noise qubit fabrication techniques can optionally be used to form the superconducting device layer.

In a first example, the superconducting circuit may be a superconducting circuit having a main chip and a shield flip chip, such as superconducting circuits 400, 500, 600 of FIGS. 4 to 6, respectively. Formation of a superconducting device layer on a first surface of a first chip may include formation of noise-susceptible device wiring layer 416, 614 on an external surface of main chip 402, 602.

In a second example, the superconducting circuit may be a superconducting circuit having a qubit chip and a control flip chip, such as superconducting circuits 700, 800 of FIGS. 7 and 8, respectively. Formation of a superconducting device layer on the first surface may include formation of noise-susceptible device layer 708, 810 on an external surface of qubit chip 702, 802.

At 1004, a superconductive shield layer is formed on a first surface of a second chip. Formation of the superconductive shield layer may, for example, include deposition, planarization and/or etching a superconducting material on an external layer of the first chip. The superconducting material can optionally be one of: aluminum, niobium, and tantalum.

In the first example, in which the superconducting circuit may be one of superconducting circuits 400, 500, 600 of FIGS. 4 to 6, formation of a superconductive shield layer on a first surface of a second chip may include formation of shield layer 410, 608 on an external surface of flip chip 404, 604.

In a second example, in which the superconducting circuit may be one of superconducting circuits 700, 800 of FIGS. 7 and 8, formation of a superconductive shield layer on a first surface of a second chip may include formation of shield layer 714, 816 on an external surface of control flip chip 704, 804.

At 1006, the first chip is communicatively coupled to the second chip in a flip-chip configuration, such that the first surfaces of the first chip and the second chip are arranged to face one another. The communicative coupling includes non-galvanically coupling the superconducting device layer and the first surface of the second chip. The non-galvanic coupling can include physically separation of the superconducting device layer and the first surface of the second chip by a space or a gap. The space or the gap can consist of at least one of: air, a vacuum, and a partial vacuum. The space or the gap in combination with the superconductive shield layer can reduce magnetic and electrical interference between superconducting devices in the superconducting device layer, as previously described.

The first chip may be oriented and/or aligned with the second chip as intended in the superconducting circuit design. This includes orientation and/or alignment of the chips in the desired flip-chip configuration, such that the first surface of the first chip, including the superconducting device layer, faces the shield layer on the first surface of the second chip. In some implementations, orientation and/or alignment of the first and the second chip may include orientation and/or alignment of a footprint of the first chip with a footprint of the second chip.

In implementations such as superconducting circuits 700, 800 in which the first chip is qubit chip 702, 802 and the second chip is control flip chip 704, 804, alignment of the chips may include alignment of noise-susceptible device layer 708, 810 with communicative interface 722, 822 of multi-layer control stack 712, 814.

The chips may be oriented and/or aligned using any known fabrication techniques and tools. For instance, a clamping device can be used to hold at least one of the first and the second chips in place as a fixed orientation and location around which the other chip can be oriented and aligned. Any suitable measurement device or tool may be used during the orienting and/or aligning of the chips.

The communicative coupling can be mechanical coupling that does not introduce additional noise to the superconducting circuit. Mechanical coupling of the first chip to the second chip can cause the superconducting device layer and the second chip to maintain a fixed distance from one another, providing the separation space, gap, or layer. The separation space, gap, or layer may have a depth such that the first and the second chip are in close proximity to one another.

In some implementations, the first chip can be mechanically coupled to the second chip using at least a mechanical coupler. The mechanical coupler may hold the first chip and the second chip at the fixed distance from one another to form the separation space, gap, or layer. The separation space, gap, or layer can be a space or gap filled with air an air layer, and/or a vacuum or partial vacuum layer across the entire cross-section of the superconducting circuit.

For instance, the mechanical coupler may be mechanical coupler 412 described with respect to superconducting circuits 400, 500 or mechanical coupler 820 described with respect to superconducting circuit 800. In an example, mechanical coupler 412 can be used to fix main chip 402 and flip chip 404 at a distance from one another to provide separation space, gap, or layer 406, which may ensure that no galvanic contact is made between noise-susceptible device wiring layer 416 and shield layer 410 on opposing chips. Likewise, mechanical coupler 820 can be used to establish separation space, gap, or layer 806 in superconducting circuit 800 to prevent noise-susceptible device layer 810 from electrically coupling to the multi-layer control stack 814 and/or shield layer 816 on control flip chip 804.

Additionally or alternatively, the first chip can be mechanically coupled to the second chip using any suitable adhesive, such as a non-conductive adhesive. Use of an adhesive may be appropriate for coupling the first chip to the second chip in implementations of the superconducting circuit where the separation space, gap, or layer is provided by a trench on the first surface of the second chip.

In some implementations, fabrication of the superconducting circuit can optionally include providing the trench by etching a portion of material from the first surface of the second chip. Any suitable etching techniques, including suitable chemical or mechanical etching may be employed. The etched portions may afterwards undergo planarization to ensure the exposed surfaces are level.

Providing a trench via etching may be achieved by first determination of a region along a cross-section of the superconductive shield layer that is aligned with the superconducting device layer when the first chip and the second chip are arranged to face one another in the flip-chip configuration. Then, a portion of the material may be etched from the superconductive shield layer to form the trench. The trench may have a width exceeding the width of the determined region and may be centered around the determined region. The separation space, gap, or layer may be provided by arrangement of the first chip to lie flush against an unetched portion of the superconductive shield layer in the flip-chip configuration to close the trench, such that side walls of the trench partially surround the superconducting device layer. As a result, the superconducting device layer is encased by a combination of: side walls of the trench, a surface of the trench parallel to an external surface of the first chip, and a portion of a substrate of the first chip.

For example, separation space, gap, or layer 620 of superconducting circuit 600 is formed in FIG. 6B when main chip 602 and flip chip 604 are oriented, aligned and physically coupled to one another. Closing trench 630 of flip chip 604 provides the unfilled area comprising separation space, gap, or layer 620, and side walls of trench 630 partially surround noise-susceptible device wiring layer 614.

In implementations in which the flip chip is a control flip chip, providing the trench by etching a portion of material from the first surface of the second chip, and can optionally include etching an entire depth of a portion of the shield material to expose an external surface of a multi-layer control stack. In implementations in which a communicative interface of a control circuit within the multi-layer control stack is not located on the external surface of the multi-layer control stack, providing the trench can optionally further include etching a portion of material from the multi-layer control stack to expose the communicative interface. Subsequent to the etching, the separation space, gap, or layer is formed by arrangement of the first chip to lie flush against an unetched portion of the superconductive shield layer in the flip-chip configuration. The trench may be etched to have a width such that the superconducting device layer is encased by a combination of: side walls of the trench, a surface of the trench parallel to an external surface of the superconducting device layer, and a portion of the first chip. As well, the trench may be etched to have a depth that enables the exposed communicative interface of the control circuit to transmit signals having an acceptably small amount of degradation to the superconducting device layer.

For example, separation space, gap, or layer 720 of superconducting circuit 700 is formed in FIG. 7B when qubit chip 702 and control flip chip 704 are aligned and physically coupled to one another. A portion of material may have been etched from the first surface of control flip chip 704 to form trench 730 that, when closed, partially surrounds or shields noise-susceptible device layer 708 and communicative interface 722, such that noise-susceptible device layer 708 is encased by: side walls of trench 730, a surface of trench 730 that is substantially parallel to the external surface of noise-susceptible device layer 708, and a portion of substrate 706. A portion of the material may also have been etched from multi-layer control stack 712 adjacent to shield layer 714 to expose communicative interface 722, if necessary.

In an alternative embodiment, fabrication of the superconducting circuit can optionally include providing the trench by a selective build-up of materials forming the second chip. For instance, in an implementation in which the flip chip is a shield flip chip, a mask may be applied to a region along the cross-sectional area part-way through deposition of the superconducting material that forms the superconductive shield layer. After the mask has been applied, additional superconducting material may be deposited to provide the remaining portion of the superconductive shield layer. Subsequent to the deposition of the additional superconducting material, the mask can be removed using any suitable technique. The amount of additional superconducting material deposited may determine the depth of the separation space, gap, or layer once the first chip and the second chip are fixed in the flip-chip arrangement.

As another example, in an implementation in which the flip chip is a control flip chip, the superconductive shield layer may also be patterned on a portion of an external layer of the multi-level control stack that excludes the communicative interface. In some instances, a mask may be placed on top of the communicative interface. Additional material used to form the multi-level control stack and/or the superconductive shield layer may be deposited after application of the mask. Then, the mask may be removed using any suitable technique to expose the communicative interface across the separation space, gap, or layer from the superconducting device layer once the first chip and the second chip are arranged in the flip-chip configuration.

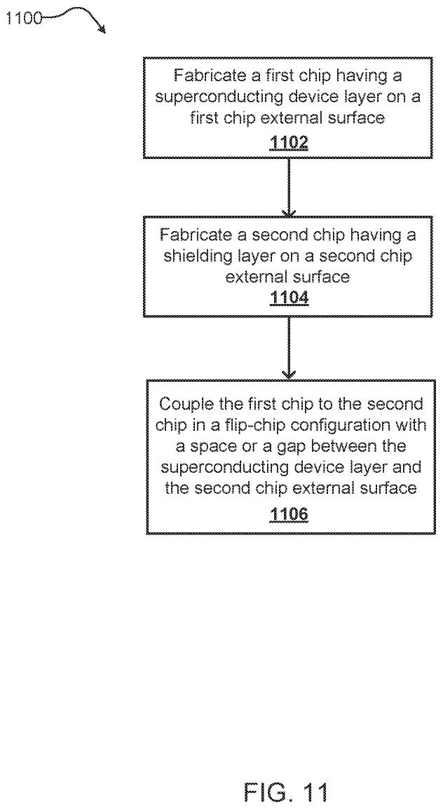

In fabrication of the superconducting circuits in accordance with the present disclosure, the first chip and the second chip may be fabricated separately from one another before being coupled to one another. This can be shown in the flowchart of FIG. 11, which illustrates a method 1100 to fabricate a superconducting integrated circuit having a flip-chip configuration for high coherence, in accordance with the present articles and methods. Method 1100 provides an example method to fabricate any one of superconducting circuits 400, 500, 600, 700, and 800.

Method 1100 includes acts 1102 to 1106, though in other implementations, certain acts may be omitted and/or additional acts may be added. Method 1000 may be performed by, for example, integrated circuit fabrication equipment in response to an initiation of a fabrication process.

At 1102, a first chip is fabricated having a superconducting device layer on a first chip external surface.

At 1104, a second chip is fabricated having a superconductive shield layer on a second chip external surface.

In implementations in which the flip chip is a shield flip chip, such as the circuits of FIGS. 4, 5, and 6, fabrication of the first chip at 1102 can involve fabrication of main chip 402, 602. This may further include formation of a first substrate, formation of a multi-layer stack, and then formation of the superconducting device layer on a portion of an external surface of the multi-layer stack. Formation of the external surface of the multi-layer stack may include deposition of a layer of a low-loss insulating material, and then planarization of the resultant insulating layer. Optionally, fabrication of the first chip may include formation of a ground plane on a second portion of the external surface of the multi-layer stack by deposition and planarization of a suitable material.

In the shield flip-chip implementations, fabrication of the second chip at 1104 can involve fabrication of flip chip 404, 604. This may include formation of a second substrate, and then formation of the superconductive shield layer on an external surface of the second substrate. Optionally, formation of the second chip may include etching a portion of the superconductive shield layer or application of a mask part-way through deposition of the material that forms the superconductive shield layer, as described above.

In implementations in which the flip chip is a control flip chip, such as the circuits of FIGS. 7A, 7B, and 8, fabrication of the first chip at 1102 can involve fabrication of qubit chip 702, 802. This may further include formation of a first substrate and then formation of the superconducting device layer on a portion of the external surface of the first substrate. Optionally, fabrication of the first chip may include formation of a ground plane on a second portion of the external surface of the first substrate by deposition and planarization of a suitable material.

In such control flip-chip implementations, fabrication of the second chip at 1104 can involve formation of control flip chip 704, 804. This may include formation of a second substrate, formation of a multi-layer stack adjacent to the second substrate, and then formation of the superconductive shield layer on a portion of an external surface of the multi-layer stack. Optionally, fabrication of the second chip may include etching a portion of the superconductive shield layer and/or multi-layer stack to expose communicative interface 722 of a control circuit within the multi-layer stack. Alternatively, but still optionally, formation of the second chip may include application of a mask on top of the communicative interface 722 before deposition of the material that forms the superconductive shield layer, as described above.

Formation of the multi-layer stack may occur as part of 1102 or 1104 depending on the implementation. Formation of the multi-layer stack may include, for example, deposition, planarization and/or etching one or more: superconducting wiring layers, interlayer dielectrics, kinetic inductance layers, and interlayer shield layers. Formation of the multi-layer stack may also forming one or more Josephson junction, which may optionally include performance of double-angle evaporation. As well, formation of the multi-layer stack may also include drilling one or more vias, and/or plating the vias with superconducting material to superconductingly electrically couple structures across layers of the multi-layer stack.

Subsequent to the separate fabrication of the first and the second chips, the first and second chips are coupled together in a flip-chip configuration with a separation space, gap, or layer between the superconducting device layer and the second chip external surface at 1106. Act 1106 may be performed as described in act 1006.

### Post-Amble

The above described method(s), process(es), or technique(s) could be implemented by a series of processor readable instructions stored on one or more nontransitory processor-readable media. Some examples of the above described method(s), process(es), or technique(s) method are performed in part by a specialized device such as an adiabatic quantum computer or a quantum annealer or a system to program or otherwise control operation of an adiabatic quantum computer or a quantum annealer, for instance a computer that includes at least one digital processor. The above described method(s), process(es), or technique(s) may include various acts, though those of skill in the art will appreciate that in alternative examples certain acts may be omitted and/or additional acts may be added. Those of skill in the art will appreciate that the illustrated order of the acts is shown for example purposes only and may change in alternative examples. Some of the example acts or operations of the above described method(s), process(es), or technique(s) are performed iteratively. Some acts of the above described method(s), process(es), or technique(s) may be performed during each iteration, after a plurality of iterations, or at the end of all the iterations.

The above description of illustrated implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. The teachings provided herein of the various implementations can be applied to other methods of quantum computation, not necessarily the example methods for quantum computation generally described above.

The various implementations described above can be combined to provide further implementations. All of the commonly assigned U.S. patent application publications, U.S. patent applications, foreign patents, and foreign patent applications referred to in this specification and/or listed in the Application Data Sheet are incorporated herein by reference, in their entirety, including but not limited to: U.S. Pat. Nos. 7,533,068; 7,687,938; 7,876,248; 8,008,942; 8,035,540; 8,098,179; 8,195,596; 8,190,548; 8,421,053; 8,854,074; 8,951,808, 9,134,047; 9,424,526; 9,768,371; 10,378,803; and 11,127,893; U.S. Patent Application Publications No. 2018/0101786; 2018/02219150; and 2020/0054961; and, International Patent Publications No. 2022/178130 and 2021/231224.

These and other changes can be made to the implementations in light of the above-detailed description. In general, in the following claims, the terms used should not be construed to limit the claims to the specific implementations disclosed in the specification and the claims, but should be construed to include all possible implementations along with the full scope of equivalents to which such claims are entitled. Accordingly, the claims are not limited by the disclosure.

1. A superconducting circuit comprising:
a first chip, wherein a superconducting device layer is a portion of a first surface of the first chip, and the superconducting device layer includes at least a portion of at least one superconducting device; and
a second chip, wherein a superconductive shield layer is at least a portion of a first surface of the second chip, the second chip communicatively coupled to the first chip such that the first surfaces of the first chip and the second chip face one another,
wherein the superconducting device layer and the first surface of the second chip are non-galvanically coupled, and physically separated by a space or a gap, the space or the gap consisting of at least one of: air, a vacuum, and a partial vacuum, and
wherein a combination of the superconductive shield layer and the space or the gap reduces magnetic and electrical interference between superconducting devices in the superconducting device layer.

2. The superconducting circuit of claim 1, wherein at least one of the first chip and the second chip are mechanically coupled to one another or to an additional surface such that a fixed distance is maintained between the superconducting device layer and the first surface of the second chip.

3. The superconducting circuit of claim 2, wherein the additional surface comprises an electrically insulating material.

4. The superconducting circuit of claim 2, wherein the at least one of the first chip and the second chip are mechanically coupled to one another or to the additional surface by a mechanical coupler, wherein:
the mechanical coupler couples at least one of the first chip and the second chip to a fixed external surface, or
the mechanical coupler couples the first chip to the second chip, and the mechanical coupler is coupled to the first chip at a location that avoids physical contact and conductive coupling with the superconducting device layer.

5. The superconducting circuit of claim 1, wherein the space or the gap is provided by a trench on the first surface of the second chip, the trench centered around the superconducting device layer along a cross-section of the superconducting circuit,
wherein the trench has a trench width exceeding a width of the superconducting device layer,
and the first chip lies flush against a region of the first surface of the second chip that does not include the trench, such that side walls of the trench at least partially surround the superconducting device layer.

6. The superconducting circuit of claim 5, wherein communicative coupling of the second chip to the first chip includes an adhesive to mechanically couple the first chip to the region of the first surface of the second chip that does not include the trench.

7. The superconducting circuit of claim 1, wherein the superconductive shield layer comprises a superconducting metal that exhibits superconducting behavior at and below a critical temperature, wherein the superconducting metal is one of: aluminum, niobium, and tantalum.

8. The superconducting circuit of claim 1, wherein the first chip comprises a ground plane, the ground plane occupies a second portion of the first surface of the first chip.

9. The superconducting circuit of claim 1, wherein the at least a portion of at least one superconducting device comprises at least a portion of one or more superconducting qubits.

10. The superconducting circuit of claim 9, wherein the at least a portion of the one or more superconducting qubits includes a respective superconducting loop of each of the one or more superconducting qubits.

11. The superconducting circuit of claim 9, wherein the least a portion of the one or more superconducting qubits includes a respective Josephson junction of each of the one or more superconducting qubits.

12. The superconducting circuit of claim 1, wherein the at least a portion of at least one superconducting device comprises: at least a portion of at least two superconducting qubits and at least a portion of at least one coupling device, wherein the at least one coupling device is operable to provide communicative coupling between the at least two superconducting qubits.

13. The superconducting circuit of claim 12, wherein the at least a portion of at least two superconducting qubits and the at least a portion of at least one coupling device comprises, for each superconducting qubit and each coupling device, one or more of: a superconducting loop and a Josephson junction.

14. The superconducting circuit of claim 1, wherein the at least a portion of the at least one superconducting device in the superconducting device layer comprises a low-noise superconducting material, the low-noise superconducting material exhibiting superconducting behavior at and below a critical temperature.

15. The superconducting circuit of claim 14, wherein the low-noise superconducting material is aluminum.

16. The superconducting circuit of claim 1, wherein:
the second chip comprises a second chip substrate that lies adjacent to the superconductive shield layer, the second chip substrate having an external surface that opposes the superconductive shield layer, and
the first chip comprises a first chip substrate and a multi-layer stack, the first chip substrate having an external surface that opposes the superconducting device layer, wherein the multi-layer stack lies between the superconducting device layer and the first chip substrate, and the multi-layer stack includes an external stack layer that lies adjacent to the superconducting device layer.

17. The superconducting circuit of claim 16, wherein the external stack layer of the multi-layer stack comprises a low-loss insulating material.

18. The superconducting circuit of claim 17, wherein the low-loss insulating material is one of: a single-crystal silicon or sapphire.

19. The superconducting circuit of claim 16, wherein the at least a portion of at least one superconducting device includes, for each superconducting device, a respective superconducting loop.

20. The superconducting circuit of claim 19, wherein a second portion of each superconducting device is a respective Josephson junction that lies within the superconducting device layer.

21. The superconducting circuit of claim 19, wherein a second portion of each superconducting device comprises a respective Josephson junction, and each Josephson junction lies within the multi-layer stack in one of: a layer in near proximity to the superconducting device layer or a layer in near proximity to the first chip substrate, and
the second portion of each superconducting device further comprises a via plated with superconducting material that superconductingly electrically couples the Josephson junction to a respective superconducting loop.

22. The superconducting circuit of claim 1, wherein:
the second chip comprises a multi-layer control stack adjacent to the superconductive shield layer, the multi-layer control stack including at least one superconducting device control circuit that comprises at least one communicative interface, wherein the at least one communicative interface is located on an external stack layer of the multi-layer control stack and lies adjacent to the space or the gap; and
the first chip includes a first chip substrate that lies adjacent to the superconducting device layer.

23. The superconducting circuit of claim 22, wherein the at least one communicative interface is operable to inductively communicate with the at least one superconducting device on the first chip.

24. The superconducting circuit of claim 22, wherein the external stack layer of the multi-layer control stack occupies a second portion of the first surface of the second chip, such that each communicative interface of the at least one communicative interface is aligned along a cross-section of the superconducting circuit with a respective superconducting device of the at least one superconducting device in the superconducting device layer.

25. The superconducting circuit of claim 22, wherein a depth of the space or the gap that separates the at least one communicative interface from the at least one superconducting device in the superconducting device layer has a size such that control signals are transmissible thereacross.

26. The superconducting circuit of claim 22, wherein the space or the gap is provided by a trench on the first surface of the second chip, wherein:
the trench is located along a cross-section of the superconducting circuit that is centered around the superconducting device layer and includes a location of the at least one communicative interface,
the trench has a trench width exceeding a width of the superconducting device layer, and
the first chip lies flush against the portion of the first surface of the second chip that comprises the superconductive shield layer, such that a number of side walls of the trench partially surround the superconducting device layer and the at least one communicative interface.

27. The superconducting circuit of claim 1, wherein:
the first chip includes a first chip substrate that comprises an electrically insulating material, wherein an external surface of the first chip substrate is a second surface of the first chip that opposes the superconducting device layer; and,
the second chip includes a second chip substrate that comprises a same or different electrically insulating material, wherein an external surface of the second chip substrate is a second surface of the second chip that opposes the superconductive shield layer.

28. The superconducting circuit of claim 27, wherein the first chip substrate comprises one of: sapphire, quartz, and single-crystal silicon, and the second chip substrate comprises a same or different one of: sapphire, quartz, and single-crystal silicon.

29. The superconducting circuit of claim 27, wherein at least the first chip substrate comprises a material having a loss tangent less than 10⁶.

30. The superconducting circuit of claim 13, wherein the superconductive shield layer of the second chip is electrically coupled to the ground plane of the first chip at one or more locations.

31. The superconducting circuit of claim 30, wherein the superconductive shield layer of the second chip is electrically coupled to the ground plane of the first chip by at least one bump bond.

32. A method of fabrication of a superconducting circuit comprising:
forming a superconducting device layer on a portion of a first surface of a first chip, the superconducting device layer including at least a portion of at least one superconducting device;
forming a superconductive shield layer on at least a portion of a first surface of a second chip; and
communicatively coupling the first chip to the second chip such that the first surfaces of the first chip and the second chip face one another, the communicatively coupling including non-galvanically communicatively coupling the superconducting device layer and the first surface of the second chip, the non-galvanically coupling including: physically separating the superconducting device layer and the first surface of the second chip by a space or a gap, the space or the gap consisting of at least one of: air, a vacuum, and a partial vacuum, and, a combination of the superconductive shield layer and the space or the gap reduces magnetic and electrical interference between superconducting devices in the superconducting device layer.

33. The method of claim 32, wherein the communicatively coupling the first chip to the second chip further comprises mechanically coupling at least one of the first chip and the second chip to one another or to an additional surface, wherein the mechanically coupling the at least one of the first chip and the second chip maintains a fixed distance between the superconducting device layer and the first surface of the second chip.

34. The method of claim 33, wherein the mechanically coupling the at least one of the first chip and the second chip to one another or to the additional surface comprises mechanically coupling the at least one of the first chip and the second chip to the additional surface, wherein the additional surface comprises an electrically insulating material.

35. The method of claim 33, wherein the mechanically coupling the at least one of the first chip and the second chip to one another or to the additional surface comprises use of a mechanical coupler for one of:
coupling at least one of the first chip and the second chip to a fixed external surface, and
coupling the first chip to the second chip, wherein the mechanical coupler is coupled to the first chip at a location that avoids physical contact and conductive coupling with the superconducting device layer.

36. The method of claim 32, wherein physically separating the superconducting device layer and the first surface of the second chip comprises:
determining a region along a cross-section of the superconductive shield layer that is aligned with the superconducting device layer when the first surfaces of the first chip and the second chip are arranged to face one another;
etching a portion of material from the superconductive shield layer having a trench width exceeding a width of the determined region and being centered around the determined region to form a trench; and
arranging the first chip to lie flush against an unetched portion of the superconductive shield layer in a flip-chip configuration to close the trench, wherein side walls of the trench at least partially surround the superconducting device layer.

37. The method of claim 36, wherein the communicatively coupling the first chip to the second chip further comprises mechanically coupling the unetched portion of the superconductive shield layer to the first chip using an electrically non-conductive adhesive.

38. The method of claim 32, wherein the forming the superconductive shield layer comprises depositing a layer of a superconducting metal on the second chip, wherein the superconducting metal exhibits superconducting behavior at and below a critical temperature, wherein the superconducting metal is one of: aluminum, niobium, and tantalum.

39. The method of claim 32, wherein the method further comprises forming a ground plane on a second portion of the first surface of the first chip.

40. The method of claim 32, wherein the forming the superconducting device layer comprises forming at least a portion of one or more superconducting qubits.

41. The method of claim 40, wherein the forming at least a portion of one or more superconducting qubits comprises forming a respective superconducting loop of each qubit of the one or more superconducting qubits.

42. The method of claim 40, wherein the forming at least the portion of one or more superconducting qubits comprises forming a respective Josephson junction of each qubit of the one or more superconducting qubits using double-angle evaporation or a single-layer fabrication technique.

43. The method of claim 32, wherein the forming the superconducting device layer comprises forming at least a portion of at least two superconducting qubits, and forming at least a portion of at least one coupling device, wherein the at least one coupling device is operable to provide communicative coupling between the at least two superconducting qubits.

44. The method of claim 43, wherein the forming at least the portion of at least two superconducting qubits and the at least a portion of at least one coupling device comprises, for each superconducting qubit and each coupling device, one or more of: forming a superconducting loop, and forming a Josephson junction.

45. The method of claim 32, wherein the forming the superconducting device layer comprises forming the at least a portion of the at least one superconducting device from a low-noise superconducting material that exhibits superconducting behavior at and below a critical temperature.

46. The method of claim 45, wherein the forming the at least a portion of the at least one superconducting device from a low-noise superconducting material comprises forming the at least a portion of the at least one superconducting device from aluminum.

47. The method of claim 32, wherein:
the first chip includes a first chip substrate including an external surface of the first chip that opposes the superconducting device layer, and the second chip includes a second chip substrate including an external surface of the second chip that opposes the superconductive shield layer, and
the forming the superconductive shield layer comprises forming the superconductive shield layer adjacent to the second chip substrate, and
the forming the superconducting device layer on a portion of the first surface of the first chip comprises forming the superconducting device layer on an external stack layer of a multi-layer stack, wherein the multi-layer stack is formed between the superconducting device layer and the first chip substrate.

48. The method of claim 47, further comprising forming the external stack layer of the multi-layer stack from a low-loss insulating material.

49. The method of claim 48, wherein the forming the external stack layer of the multi-layer stack from the low-loss insulating material comprises forming the low-loss insulator from a single-crystal silicon or sapphire.

50. The method of claim 47, wherein the forming the superconducting device layer on a portion of the first surface of the first chip comprises forming a first portion of the at least one superconducting device in the superconducting device layer, and for each superconducting device, the forming the first portion of the at least one superconducting device comprises forming a respective superconducting loop.

51. The method of claim 50, wherein, for each superconducting device, forming a second portion of the at least one superconducting device comprises forming a respective Josephson junction in the superconducting device layer.

52. The method of claim 50, wherein for each superconducting device, forming a second portion of the at least one superconducting device comprises forming a respective Josephson junction within the multi-layer stack at one of: a layer in near proximity to the superconducting device layer or a layer in near proximity to the first chip substrate; and
forming a via to connect the Josephson junction to a respective first portion of the superconducting device, and plating the via with a superconducting material to superconductingly electrically couple a respective first and the second portion of the superconducting device.

53. The method of claim 32, further comprising forming a multi-layer control stack adjacent to the superconductive shield layer, the multi-layer control stack including at least one superconducting control circuit that comprises at least one communicative interface, wherein the forming the multi-layer control stack comprises forming an external stack layer including the at least one communicative interface lying adjacent to the space or the gap, and
the forming the superconducting device layer on the first surface of the first chip comprises forming the superconducting device layer to lie adjacent to a first chip substrate.

54. The method of claim 53, wherein the forming the external stack layer including the at least one communicative interface comprises forming the at least one communicative interface to be operable to inductively communicate with the at least one superconducting device on the first chip.

55. The method of claim 53, wherein the forming the external stack layer including the at least one communicative interface adjacent to the space or the gap comprises: forming the external stack layer of the multi-layer control stack on a second portion of the first surface of the second chip, and
determining a location of the second portion of the first surface of the second chip includes aligning, along a cross-section of the superconducting circuit, each communicative interface of the at least one communicative interface with a respective superconducting device of the at least one superconducting device in the superconducting device layer.

56. The method of claim 55, wherein the physically separating the superconducting device layer and the first surface of the second chip by the space or the gap comprises separating the at least one communicative interface at a depth from the at least one superconducting device in the superconducting device layer, wherein the depth has a size such that control signals are transmissible between the at least one communicative interface and the at least one superconducting device across the space or the gap.

57. The method of claim 53, wherein:
the forming the superconductive shield layer comprises:
forming the superconductive shield layer adjacent to the external stack layer of the multi-layer control stack, and
etching a portion of material from at least the superconductive shield layer that overlies the at least one communicative interface to form a trench, such that the at least one communicative interface is on a surface of the trench adjacent to the space or the gap, the trench having a trench width exceeding a width of the superconducting device layer and being centered around the superconducting device layer when the first and the second chip are aligned; and
the physically separating the superconducting device layer and the first surface of the second chip to form the space or the gap comprises closing the trench when the first surfaces of the first chip and second the second chip face one another by arranging the first chip to lie flush against an unetched portion of the superconductive shield layer, wherein side walls of the trench at least partially surround the at least one communicative interface and the superconducting device layer.

58. The method of claim 32, the fabrication of the superconducting circuit further comprising:
forming the first chip having a first substrate comprised of an electrically insulating material, wherein an external surface of the first substrate is a second surface of the first chip that opposes the superconducting device layer; and,
forming the second chip having a second substrate comprised of a same or different electrically insulating material, wherein an external surface of the second substrate is a second surface of the second chip that opposes the superconductive shield layer.

59. The method of claim 58, wherein the forming the first chip having the first substrate and the forming the second chip having the second substrate comprises forming the first substrate from one of: sapphire, quartz, and a single-crystal silicon, and forming the second substrate from a same or different one of: sapphire, quartz, and a single-crystal.

60. The method of claim 58, wherein at least the forming the first chip having the first substrate comprises forming the first substrate from a substrate material having a loss tangent less than 10⁶.

61. The method of claim 39, wherein the method further comprises electrically coupling the superconductive shield layer of the second chip to the ground plane of the first chip at one or more locations.

62. The method of claim 61, wherein the electrically coupling the superconductive shield layer of the second chip to the ground plane of the first chip includes forming at least one bump bond between the superconductive shield layer of the second chip and the ground plane of the first chip.

63. A superconducting circuit comprising:
a first chip, the first chip comprising a superconducting device layer, wherein the superconducting device layer is a portion of a first surface of the first chip and includes at least a portion of at least one superconducting device; and
a second chip, the second chip comprising:
a multi-layer control stack comprising at least a plurality of superconducting wiring layers, the plurality of superconducting wiring layers operable to provide at least one superconducting device control circuit including at least one communicative interface on a first portion of a first surface of the second chip, and
a superconductive shield layer overlying a portion of the multi-layer control stack, the superconductive shield layer occupying a second portion of the first surface of the second chip,
wherein the first chip and the second chip are communicatively coupled with the first surfaces of the first chip and the second chip facing one another and with a space or a gap to maintain a physical distance between the superconducting device layer and the first surface of the second chip, the space or the gap consisting of at least one of: air, a vacuum, and a partial vacuum, and the superconducting device layer and the first surface of the second chip are non-galvanically coupled, and
wherein a combination of the superconductive shield layer and the space or the gap reduces magnetic and electrical interference between superconducting devices in the superconducting device layer.

64. A superconducting circuit comprising:
a first chip, the first chip comprising a superconducting device layer, wherein the superconducting device layer is a portion of a first surface of the first chip and includes at least a portion of at least one superconducting device; and
a second chip, the second chip comprising:
a multi-layer control stack comprising at least one superconducting device control circuit that includes at least one communicative interface, the at least one communicative interface located on a first portion of a first surface of the second chip,
a superconductive shield layer overlying a portion of the multi-layer control stack, wherein the shield layer occupies a second portion of the first surface of the second chip, and
wherein the first portion of the first surface of the second chip is located on an external surface of a trench in the second chip, the trench filled with at least one of: air, a vacuum, and a partial vacuum,
wherein a second portion of the first surface of the first chip and the second portion of the first surface of the second chip are communicatively coupled to one another such that the superconducting device layer and the at least one communicative interface are separated by a depth of the trench and at least partially surrounded by side walls of the trench, and
wherein a combination of the superconductive shield layer and the space or the gap reduces magnetic and electrical interference between superconducting devices in the superconducting device layer.
